(19) United States
(12) Patent Application Publication
(10) Pub. No.: US 2025/0386592 A1
(43) Pub. Date: Dec. 18, 2025

(54) STACKED SEMICONDUCTOR STRUCTURE WITH OPPOSITE POLARITY TRANSISTORS

(71) Applicant: International Business Machines Corporation, Armonk, NY (US)

(72) Inventors: Debarghya Sarkar, Latham, NY (US); Shay Reboh, Guilderland, NY (US); Ruilong Xie, Niskayuna, NY (US); Wai Kin Li, Albany, NY (US); Takashi Ando, Eastchester, NY (US); Junli Wang, Slingerlands, NY (US)

(21) Appl. No.: 18/746,854

(22) Filed: Jun. 18, 2024

(51) Int. Cl. H01L 27/088; H01L 27/092; H01L 29/66; H01L 29/78; H01L 29/786

(52) U.S. Cl. CPC H10D 84/834; H10D 30/62; H10D 30/6757; H10D 64/017; H10D 64/021; H10D 84/85

(57) ABSTRACT

A semiconductor device includes at least one stacked device structure including at least one upper transistor device including one or more upper channel layers, and at least one lower transistor device including one or more lower channel layers, and at least two high-k free dielectric layers. The semiconductor device also includes a common gate structure including a metal fill portion, where a first side of the metal fill portion contacts a first one of the at least two high-k free dielectric layers, and a second side of the metal fill portion contacts a second one of the at least two high-k free dielectric layers.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Illustrative embodiments of the present application include techniques for use in semiconductor manufacture. In an illustrative embodiment, a semiconductor device includes at least one stacked device structure including at least one upper transistor device including one or more upper channel layers, and at least one lower transistor device including one or more lower channel layers, and at least two high-k free dielectric layers. The semiconductor device also includes a common gate structure including a metal fill portion, where a first side of the metal fill portion contacts a first one of the at least two high-k free dielectric layers, and a second side of the metal fill portion contacts a second one of the at least two high-k free dielectric layers.

In another illustrative embodiment, a semiconductor device includes at least one stacked transistor structure including at least one n-type transistor device and at least one p-type transistor device adjacent to the least one n-type transistor device, at least two high-k free dielectric layers, and a common gate structure. The common gate structure includes a continuous metal fill portion, where a bottom surface of the continuous metal fill portion directly contacts a first one of the at least two high-k free dielectric layers, and a top surface of the continuous metal fill portion directly contacts a second one of the at least two high-k free dielectric layers.

In another exemplary embodiment, a method includes removing first portions of a sacrificial gate layer surrounding one or more upper channel layers of an upper transistor device of semiconductor structure, where the semiconductor structure includes a lower transistor device comprising one or more lower channel layers, and forming a first high-K metal gate structure that covers at least exposed surfaces of the one or more upper channel layers. The method includes filling the removed first portions of the sacrificial gate layer with a metal gate material, removing second portions of the sacrificial gate layer that surround the one or more lower channel layers, and forming a second high-K metal gate structure that covers at least exposed surfaces of the one or more lower channel layers. The method also includes filling the removed second portions of the sacrificial gate layer with the metal gate material to form a common gate structure, where the metal gate material is continuous between the upper transistor device and the lower transistor device, and where a bottom surface of the metal gate material directly contacts a first high-k free dielectric layer, and a top surface of the metal gate material directly contacts a second high-k free dielectric layer.

Other embodiments will be described in the following detailed description of embodiments, which is to be read in conjunction with the accompanying figures.

### BRIEF DESCRIPTION OF THE DRAWINGS

FIG. 1 depicts a top view of a semiconductor structure with lines X1, X2, Y1, and Y2 on which the cross-sectional views of FIGS. 2A-33D are based, according to an illustrative embodiment.

FIG. 2A depicts a first cross-sectional view corresponding to line X1 in FIG. 1 illustrating the semiconductor structure of FIG. 1 during an intermediate step of a method of fabricating a nanosheet transistor structure, according to an illustrative embodiment.

FIG. 2B depicts a second cross-sectional view corresponding to line Y1 in FIG. 1 illustrating the semiconductor structure of FIG. 1 during the intermediate step of the method of fabricating the nanosheet transistor structure, according to an illustrative embodiment.

FIG. 2C depicts a third cross-sectional view corresponding to line Y2 in FIG. 1 illustrating the semiconductor structure of FIG. 1 during the intermediate step of the method of fabricating the nanosheet transistor structure, according to an illustrative embodiment.

FIG. 2D depicts a fourth cross-sectional view corresponding to line X2 in FIG. 1 illustrating the semiconductor structure of FIG. 1 during the intermediate step of the method of fabricating the nanosheet transistor structure, according to an illustrative embodiment.

FIG. 3A depicts a first cross-sectional view corresponding to the line X1 in FIG. 1 following formation of a dielectric protection layer, according to an illustrative embodiment.

FIG. 3B depicts a second cross-sectional view corresponding to the line Y1 in FIG. 1 following the formation of the dielectric protection layer, according to an illustrative embodiment.

FIG. 3C depicts a third cross-sectional view corresponding to the line Y2 in FIG. 1 following the formation of the dielectric protection layer, according to an illustrative embodiment.

FIG. 3D depicts a fourth cross-sectional view corresponding to the line X2 in FIG. 1 following the formation of the dielectric protection layer, according to an illustrative embodiment.

FIG. 4A depicts a first cross-sectional view corresponding to the line X1 in FIG. 1 following top source/drain region formation, according to an illustrative embodiment.

FIG. 4B depicts a second cross-sectional view corresponding to the line Y1 in FIG. 1 following the top source/drain region formation, according to an illustrative embodiment.

FIG. 4C depicts a third cross-sectional view corresponding to the line Y2 in FIG. 1 following the top source/drain region formation, according to an illustrative embodiment.

FIG. 4D depicts a fourth cross-sectional view corresponding to the line X2 in FIG. 1 following the top source/drain region formation, according to an illustrative embodiment.

FIG. 5A depicts a first cross-sectional view corresponding to the line X1 in FIG. 1 following a dielectric fill process, according to an illustrative embodiment.

FIG. 5B depicts a second cross-sectional view corresponding to the line Y1 in FIG. 1 following the dielectric fill process, according to an illustrative embodiment.

FIG. 5C depicts a third cross-sectional view corresponding to the line Y2 in FIG. 1 following the dielectric fill process, according to an illustrative embodiment.

FIG. 5D depicts a fourth cross-sectional corresponding to the line X2 in FIG. 1 following the dielectric fill process, according to an illustrative embodiment.

FIG. 6A depicts a first cross-sectional view corresponding to the line X1 in FIG. 1 following partial removal of a dummy gate layer, according to an illustrative embodiment.

FIG. 6B depicts a second cross-sectional view corresponding to the line Y1 in FIG. 1 following the partial removal of the dummy gate layer, according to an illustrative embodiment.

FIG. 6C depicts a third cross-sectional view corresponding to the line Y2 in FIG. 1 following the partial removal of the dummy gate layer, according to an illustrative embodiment.

FIG. 6D depicts a fourth cross-sectional corresponding to the line X2 in FIG. 1 following the partial removal of the dummy gate layer, according to an illustrative embodiment.

FIG. 7A depicts a first cross-sectional view corresponding to the line X1 in FIG. 1 following etching of a dielectric liner, according to an illustrative embodiment.

FIG. 7B depicts a second cross-sectional view corresponding to the line Y1 in FIG. 1 following the etching of the dielectric liner, according to an illustrative embodiment.

FIG. 7C depicts a third cross-sectional view corresponding to the line Y2 in FIG. 1 following the etching of the dielectric liner, according to an illustrative embodiment.

FIG. 7D depicts a fourth cross-sectional corresponding to the line X2 in FIG. 1 following the etching of the dielectric liner, according to an illustrative embodiment.

FIG. 8A depicts a first cross-sectional view corresponding to the line X1 in FIG. 1 following removal of top sacrificial layers, according to an illustrative embodiment.

FIG. 8B depicts a second cross-sectional view corresponding to the line Y1 in FIG. 1 following the removal of top sacrificial layers, according to an illustrative embodiment.

FIG. 8C depicts a third cross-sectional view corresponding to the line Y2 in FIG. 1 following the removal of top sacrificial layers, according to an illustrative embodiment.

FIG. 8D depicts a fourth cross-sectional corresponding to the line X2 in FIG. 1 following the removal of top sacrificial layers, according to an illustrative embodiment.

FIG. 9A depicts a first cross-sectional view corresponding to the line X1 in FIG. 1 following top gate dielectric deposition, according to an illustrative embodiment.

FIG. 9B depicts a second cross-sectional view corresponding to the line Y1 in FIG. 1 following the top gate dielectric deposition, according to an illustrative embodiment.

FIG. 9C depicts a third cross-sectional view corresponding to the line Y2 in FIG. 1 following the top gate dielectric deposition, according to an illustrative embodiment.

FIG. 9D depicts a fourth cross-sectional corresponding to the line X2 in FIG. 1 following the top gate dielectric deposition, according to an illustrative embodiment.

FIG. 10A depicts a first cross-sectional view corresponding to the line X1 in FIG. 1 following top metal gate fill and sacrificial cap layer formation, according to an illustrative embodiment.

FIG. 10B depicts a second cross-sectional view corresponding to the line Y1 in FIG. 1 following the top metal gate fill and the sacrificial cap layer formation, according to an illustrative embodiment.

FIG. 10C depicts a third cross-sectional view corresponding to the line Y2 in FIG. 1 following the top metal gate fill and the sacrificial cap layer formation, according to an illustrative embodiment.

FIG. 10D depicts a fourth cross-sectional corresponding to the line X2 in FIG. 1 following the top metal gate fill and the sacrificial cap layer formation, according to an illustrative embodiment.

FIG. 11A depicts a first cross-sectional view corresponding to the line X1 in FIG. 1 following frontside contact formation and carrier wafer bonding, according to an illustrative embodiment.

FIG. 11B depicts a second cross-sectional view corresponding to the line Y1 in FIG. 1 following the frontside contact formation and the carrier wafer bonding, according to an illustrative embodiment.

FIG. 11C depicts a third cross-sectional view corresponding to the line Y2 in FIG. 1 following the frontside contact formation and the carrier wafer bonding, according to an illustrative embodiment.

FIG. 11D depicts a fourth cross-sectional corresponding to the line X2 in FIG. 1 following the frontside contact formation and the carrier wafer bonding, according to an illustrative embodiment.

FIG. 12A depicts a first cross-sectional view corresponding to the line X1 in FIG. 1 following wafer flipping and substrate removal, according to an illustrative embodiment.

FIG. 12B depicts a second cross-sectional view corresponding to the line Y1 in FIG. 1 following the wafer flipping and the substrate removal, according to an illustrative embodiment.

FIG. 12C depicts a third cross-sectional view corresponding to the line Y2 in FIG. 1 following the wafer flipping and the substrate removal, according to an illustrative embodiment.

FIG. 12D depicts a fourth cross-sectional corresponding to the line X2 in FIG. 1 following the wafer flipping and the substrate removal, according to an illustrative embodiment.

FIG. 13A depicts a first cross-sectional view corresponding to the line X1 in FIG. 1 following dielectric liner deposition, according to an illustrative embodiment.

FIG. 13B depicts a second cross-sectional view corresponding to the line Y1 in FIG. 1 following the dielectric liner deposition, according to an illustrative embodiment.

FIG. 13C depicts a third cross-sectional view corresponding to the line Y2 in FIG. 1 following the dielectric liner deposition, according to an illustrative embodiment.

FIG. 13D depicts a fourth cross-sectional corresponding to the line X2 in FIG. 1 following the dielectric liner deposition, according to an illustrative embodiment.

FIG. 14A depicts a first cross-sectional view corresponding to the line X1 in FIG. 1 following formation of a dielectric protection layer, according to an illustrative embodiment.

FIG. 14B depicts a second cross-sectional view corresponding to the line Y1 in FIG. 1 following dielectric liner recess and self-aligned selective frontside dielectric etch, according to an illustrative embodiment.

FIG. 14C depicts a third cross-sectional view corresponding to the line Y2 in FIG. 1 following the dielectric liner recess and the self-aligned selective frontside dielectric etch, according to an illustrative embodiment.

FIG. 14D depicts a fourth cross-sectional corresponding to the line X2 in FIG. 1 following the dielectric liner recess and the self-aligned selective frontside dielectric etch, according to an illustrative embodiment.

FIG. 15A depicts a first cross-sectional view corresponding to the line X1 in FIG. 1 following bottom source/drain region formation, according to an illustrative embodiment.

FIG. 15B depicts a second cross-sectional view corresponding to the line Y1 in FIG. 1 1 following the bottom source/drain region formation, according to an illustrative embodiment.

FIG. 15C depicts a third cross-sectional view corresponding to the line Y2 in FIG. 1 following the bottom source/drain region formation, according to an illustrative embodiment.

FIG. 15D depicts a fourth cross-sectional corresponding to the line X2 in FIG. 1 following the bottom source/drain region formation, according to an illustrative embodiment.

FIG. 16A depicts a first cross-sectional view corresponding to the line X1 in FIG. 1 following dielectric liner fill and recess, according to an illustrative embodiment.

FIG. 16B depicts a second cross-sectional view corresponding to the line Y1 in FIG. 1 following the dielectric liner recess, according to an illustrative embodiment.

FIG. 16C depicts a third cross-sectional view corresponding to the line Y2 in FIG. 1 following the dielectric liner recess, according to an illustrative embodiment.

FIG. 16D depicts a fourth cross-sectional corresponding to the line X2 in FIG. 1 following the dielectric liner recess, according to an illustrative embodiment.

FIG. 17A depicts a first cross-sectional view corresponding to the line X1 in FIG. 1 following isolation region recess, according to an illustrative embodiment.

FIG. 17B depicts a second cross-sectional view corresponding to line Y1 in FIG. 1 following the isolation region recess, according to an illustrative embodiment.

FIG. 17C depicts a third cross-sectional view corresponding to line Y2 in FIG. 1 following the isolation region recess, according to an illustrative embodiment.

FIG. 17D depicts a fourth cross-sectional corresponding to line X2 in FIG. 1 following the isolation region recess, according to an illustrative embodiment.

FIG. 18A depicts a first cross-sectional view corresponding to the line X1 in FIG. 1 following bottom dummy gate layer removal, according to an illustrative embodiment.

FIG. 18B depicts a second cross-sectional view corresponding to the line Y1 in FIG. 1 following the bottom dummy gate layer removal, according to an illustrative embodiment.

FIG. 18C depicts a third cross-sectional view corresponding to the line Y2 in FIG. 1 following the bottom dummy gate layer removal, according to an illustrative embodiment.

FIG. 18D depicts a fourth cross-sectional corresponding to the line X2 in FIG. 1 following the bottom dummy gate layer removal, according to an illustrative embodiment.

FIG. 19A depicts a first cross-sectional view corresponding to the line X1 in FIG. 1 following dielectric liner etch, according to an illustrative embodiment.

FIG. 19B depicts a second cross-sectional view corresponding to the line Y1 in FIG. 1 following the dielectric liner etch, according to an illustrative embodiment.

FIG. 19C depicts a third cross-sectional view corresponding to the line Y2 in FIG. 1 following the dielectric liner etch, according to an illustrative embodiment.

FIG. 19D depicts a fourth cross-sectional corresponding to the line X2 in FIG. 1 following the dielectric liner etch, according to an illustrative embodiment.

FIG. 20A depicts a first cross-sectional view corresponding to the line X1 in FIG. 1 following removal of bottom sacrificial layers, according to an illustrative embodiment.

FIG. 20B depicts a second cross-sectional view corresponding to the line Y1 in FIG. 1 following the removal of the bottom sacrificial layers, according to an illustrative embodiment.

FIG. 20C depicts a third cross-sectional view corresponding to the line Y2 in FIG. 1 following the removal of the bottom sacrificial layers, according to an illustrative embodiment.

FIG. 20D depicts a fourth cross-sectional corresponding to the line X2 in FIG. 1 following the removal of the bottom sacrificial layers, according to an illustrative embodiment.

FIG. 21A depicts a first cross-sectional view corresponding to the line X1 in FIG. 1 following bottom gate dielectric deposition, according to an illustrative embodiment.

FIG. 21B depicts a second cross-sectional view corresponding to the line Y1 in FIG. 1 following the bottom gate dielectric deposition, according to an illustrative embodiment.

FIG. 21C depicts a third cross-sectional view corresponding to the line Y2 in FIG. 1 following the bottom gate dielectric deposition, according to an illustrative embodiment.

FIG. 21D depicts a fourth cross-sectional corresponding to the line X2 in FIG. 1 following the bottom gate dielectric deposition, according to an illustrative embodiment.

FIG. 22A depicts a first cross-sectional view corresponding to the line X1 in FIG. 1 following self-aligned bottom gate dielectric recess, according to an illustrative embodiment.

FIG. 22B depicts a second cross-sectional view corresponding to the line Y1 in FIG. 1 following the self-aligned bottom gate dielectric recess, according to an illustrative embodiment.

FIG. 22C depicts a third cross-sectional view corresponding to the line Y2 in FIG. 1 following the self-aligned bottom gate dielectric recess, according to an illustrative embodiment.

FIG. 22D depicts a fourth cross-sectional view corresponding to the line X2 in FIG. 1 following the self-aligned bottom gate dielectric recess, according to an illustrative embodiment.

FIG. 23A depicts a first cross-sectional view corresponding to the line X1 in FIG. 1 following bottom metal gate fill, according to an illustrative embodiment.

FIG. 23B depicts a second cross-sectional view corresponding to the line Y1 in FIG. 1 following the bottom metal gate fill, according to an illustrative embodiment.

FIG. 23C depicts a third cross-sectional view corresponding to the line Y2 in FIG. 1 following the bottom metal gate fill, according to an illustrative embodiment.

FIG. 23D depicts a fourth cross-sectional view corresponding to the line X2 in FIG. 1 following the bottom metal gate fill, according to an illustrative embodiment.

FIG. 24A depicts a first cross-sectional view corresponding to the line X1 in FIG. 1 following bottom metal gate recess, according to an illustrative embodiment.

FIG. 24B depicts a second cross-sectional view corresponding to the line Y1 in FIG. 1 following the bottom metal gate recess, according to an illustrative embodiment.

FIG. 24C depicts a third cross-sectional view corresponding to the line Y2 in FIG. 1 following the bottom metal gate recess, according to an illustrative embodiment.

FIG. 24D depicts a fourth cross-sectional view corresponding to the line X2 in FIG. 1 following the bottom metal gate recess, according to an illustrative embodiment.

FIG. 25A depicts a first cross-sectional view corresponding to the line X1 in FIG. 1 following bottom dielectric fill and planarization, according to an illustrative embodiment.

FIG. 25B depicts a second cross-sectional view corresponding to the line Y1 in FIG. 1 following the bottom dielectric fill and planarization, according to an illustrative embodiment.

FIG. 25C depicts a third cross-sectional view corresponding to the line Y2 in FIG. 1 following the bottom dielectric fill and planarization, according to an illustrative embodiment.

FIG. 25D depicts a fourth cross-sectional view corresponding to the line X2 in FIG. 1 following the bottom dielectric fill and planarization, according to an illustrative embodiment.

FIG. 26A depicts a first cross-sectional view corresponding to the line X1 in FIG. 1 following backside contact patterning, according to an illustrative embodiment.

FIG. 26B depicts a second cross-sectional view corresponding to the line Y1 in FIG. 1 following the backside contact patterning, according to an illustrative embodiment.

FIG. 26C depicts a third cross-sectional view corresponding to the line Y2 in FIG. 1 following the backside contact patterning, according to an illustrative embodiment.

FIG. 26D depicts a fourth cross-sectional view corresponding to the line X2 in FIG. 1 following the backside contact patterning, according to an illustrative embodiment.

FIG. 27A depicts a first cross-sectional view corresponding to the line X1 in FIG. 1 following selective self-aligned recess, according to an illustrative embodiment.

FIG. 27B depicts a second cross-sectional view corresponding to the line Y1 in FIG. 1 following the selective self-aligned recess, according to an illustrative embodiment.

FIG. 27C depicts a third cross-sectional view corresponding to the line Y2 in FIG. 1 following the selective self-aligned recess, according to an illustrative embodiment.

FIG. 27D depicts a fourth cross-sectional view corresponding to the line X2 in FIG. 1 following the selective self-aligned recess, according to an illustrative embodiment.

FIG. 28A depicts a first cross-sectional view corresponding to the line X1 in FIG. 1 following source contact patterning for the bottom device and drain contact patterning for the top device, according to an illustrative embodiment.

FIG. 28B depicts a second cross-sectional view corresponding to the line Y1 in FIG. 1 following the source contact patterning for the bottom device and the drain contact patterning for the top device, according to an illustrative embodiment.

FIG. 28C depicts a third cross-sectional view corresponding to the line Y2 in FIG. 1 following the source contact patterning for the bottom device and the drain contact patterning for the top device, according to an illustrative embodiment.

FIG. 28D depicts a fourth cross-sectional view corresponding to the line X2 in FIG. 1 following the source contact patterning for the bottom device and the drain contact patterning for the top device, according to an illustrative embodiment.

FIG. 29A depicts a first cross-sectional view corresponding to the line X1 in FIG. 1 following recessing for the bottom source contact and for the top drain contact, according to an illustrative embodiment.

FIG. 29B depicts a second cross-sectional view corresponding to the line Y1 in FIG. 1 following the recessing for the bottom source contact and for the top drain contact, according to an illustrative embodiment.

FIG. 29C depicts a third cross-sectional view corresponding to the line Y2 in FIG. 1 following the recessing for the bottom source contact and for the top drain contact, according to an illustrative embodiment.

FIG. 29D depicts a fourth cross-sectional view corresponding to the line X2 in FIG. 1 following the recessing for the bottom source contact and for the top drain contact, according to an illustrative embodiment.

FIG. 30A depicts a first cross-sectional view corresponding to the line X1 in FIG. 1 following organic planarization layer (OPL) recessing, according to an illustrative embodiment.

FIG. 30B depicts a second cross-sectional view corresponding to the line Y1 in FIG. 1 following the OPL recessing, according to an illustrative embodiment.

FIG. 30C depicts a third cross-sectional view corresponding to the line Y2 in FIG. 1 following the OPL recessing, according to an illustrative embodiment.

FIG. 30D depicts a fourth cross-sectional view corresponding to the line X2 in FIG. 1 following the OPL recessing, according to an illustrative embodiment.

FIG. 31A depicts a first cross-sectional view corresponding to the line X1 in FIG. 1 following backside contact metal fill and planarization, according to an illustrative embodiment.

FIG. 31B depicts a second cross-sectional view corresponding to the line Y1 in FIG. 1 following the backside contact metal fill and planarization, according to an illustrative embodiment.

FIG. 31C depicts a third cross-sectional view corresponding to the line Y2 in FIG. 1 following the backside contact metal fill and planarization, according to an illustrative embodiment.

FIG. 31D depicts a fourth cross-sectional view corresponding to the line X2 in FIG. 1 following the backside contact metal fill and planarization, according to an illustrative embodiment.

FIG. 32A depicts a first cross-sectional view corresponding to the line X1 in FIG. 1 following gate interconnect formation, according to an illustrative embodiment.

FIG. 32B depicts a second cross-sectional view corresponding to the line Y1 in FIG. 1 following the gate interconnect formation, according to an illustrative embodiment.

FIG. 32C depicts a third cross-sectional view corresponding to the line Y2 in FIG. 1 following the gate interconnect formation, according to an illustrative embodiment.

FIG. 32D depicts a fourth cross-sectional view corresponding to the line X2 in FIG. 1 following the gate interconnect formation, according to an illustrative embodiment.

FIG. 33A depicts a first cross-sectional view corresponding to the line X1 in FIG. 1 following backside interconnect formation, according to an illustrative embodiment.

FIG. 33B depicts a second cross-sectional view corresponding to the line Y1 in FIG. 1 following the backside interconnect formation, according to an illustrative embodiment.

FIG. 33C depicts a third cross-sectional view corresponding to the line Y2 in FIG. 1 following the backside interconnect formation, according to an illustrative embodiment.

FIG. 33D depicts a fourth cross-sectional view corresponding to the line X2 in FIG. 1 following the backside interconnect formation, according to an illustrative embodiment.

### DETAILED DESCRIPTION

Illustrative embodiments are described herein in the context of illustrative methods for configuring stacked semiconductor structures with opposite polarity transistors, along with illustrative apparatus, systems and devices formed using such methods. However, it is to be understood that embodiments described herein are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. In FinFET structures, the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (for example, to 2.5 nm and beyond), next-generation stacked FET (SFET) devices may be used. Next-generation SFET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation SFET structures provide improved track height scaling, leading to structural gains (for example, such as 30-40% structural gains for different types of devices, such as logic devices, static random-access memory (SRAM) devices, etc.). In next-generation SFET structures, n-type, and p-type nanowires or nanosheets are stacked on each other, eliminating n-to-p separation bottlenecks, and reducing the device area footprint. There is, however, a continued desire for further scaling and reducing the size of FETs.

As discussed above, various techniques may be used to reduce the size of FETs, including using fin-shaped channels in FinFET devices, using stacked nanosheet channels formed over a semiconductor substrate, and using next-generation SFET devices.

To ensure proper operation of semiconductor structures, the material of the work function metal (WFM), as well as the source/drain regions' materials, should be matched to the polarity of a transistor device. However, challenges arise when using a stacked semiconductor structure because transistor devices with different polarities (e.g., nFETs and pFETs) are often arranged vertically within the same region of the semiconductor structure.

Conventional techniques include a blanket deposition of the WFM matched to the bottom transistor device, followed by recess from the top transistor device, and then redeposition of the WFM matched to the top transistor device. However, this process is difficult to execute reliably due to issues with atomic layer recess from the top transistor device while maintaining the integrity of the WFM of the bottom transistor device. Another technique involves applying selective vertical masking of the top transistor device during growth of the source/drain region for the bottom transistor device. However, it can be challenging to grow the source/drain region with a specific polarity to targeted nanosheets while keeping other areas isolated within the same source/drain canyon, resulting in low reliability and difficulty.

Some embodiments described herein address such challenges by recessing nanosheets in both the top and bottom transistor devices while separating high-k dielectric (HK) deposition from the source/drain region integration using a protective dielectric fill. This allows for self-aligned gate regions for the top and bottom transistor devices, with a continuous gate metal throughout the stack. As a result, there is matched WFM and source/drain region for both devices that are electrically isolated from each other within the stacked semiconductor structure, thus avoiding selective recess processes in the RMG module and growth challenges in the source/drain module.

Although embodiments described herein are discussed in connection with nanosheet stacks, the embodiments are not necessarily limited thereto, and may similarly apply to nanowire stacks.

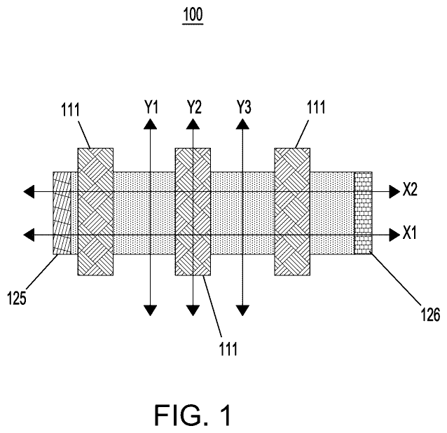

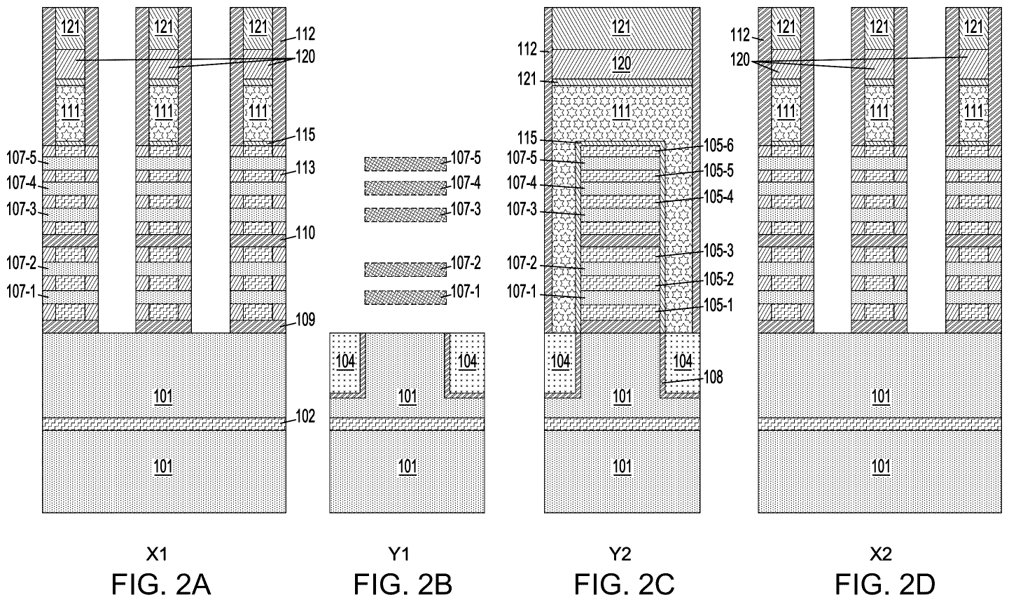

Referring to FIG. 1 and to the cross-sectional views in FIGS. 2A-2D, which respectively correspond to the lines X1, Y1, Y2, and X2 in FIG. 1, a semiconductor structure 100 includes a first transistor active area (Rx) 125 and a second transistor active area (Ry) 126. In the top view of FIG. 1, Rx and Ry overlap with each other. In some embodiments, the first transistor active area 125 is associated with a first plurality of source/drain regions, while the second transistor active area Ry can be associated with a second plurality of source/drain regions. In such embodiments, the first plurality of source/drain regions may have a different doping type (e.g., N+) than the second plurality of source/drain region (e.g., P+), as described in more detail elsewhere herein.

The semiconductor structure 100 also includes a stacked structure comprising sacrificial layers 105-1, 105-2, 105-3, 105-4, 105-5, and 105-6 (collectively “sacrificial layers 105”) and channel layers 107-1, 107-2, 107-3, 107-4, and 107-5 (collectively “channel layers 107”). In an illustrative embodiment, the sacrificial layers 105 comprise SiGe and the channel layers 107 comprise silicon. The stacked structure also includes a bottom dielectric isolation (BDI) layer 109 and middle dielectric isolation (MDI) layer 110. The BDI layer 109 and MDI layer 110 may comprise, for example, silicon oxide (SiOx) (where x is, for example, 2, 1.99 or 2.01), silicon oxycarbide (SiOC), silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN) and combinations thereof.

While six sacrificial layers 105 and five channel layers 107 are shown, the embodiments described herein are not necessarily limited to the shown number of sacrificial layers 105 and channel layers 107, and there may be more or fewer layers in the same alternating configuration, depending on design constraints. The sacrificial layers 105, as described further herein, are eventually removed, and replaced by gate structures.

The sacrificial layers 105 and the channel layers 107 are epitaxially grown on a semiconductor substrate 101. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The semiconductor substrate 101 may be formed of any suitable semiconductor structure, including various silicon-containing materials such as but not limited to Si, SiGe, silicon germanium carbide (SiGeC), silicon carbide (SiC), and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), and zinc selenide (ZnSe).

As used herein, “frontside or “first side” refers to a side on top of the semiconductor substrate 101 and/or in front of, on top of or in an upward direction from the stacked gate and channel layers of the transistors in the orientation shown in the cross-sectional figures. As used herein, “backside” or “second side” refers to a side below the semiconductor substrate 101 and/or behind, below or in a downward direction from the stacked gate and channel layers of the transistors in the orientation shown in the cross-sectional figures (for example, opposite the “frontside”).

An etch stop layer 102 is formed in the semiconductor substrate 101. The etch stop layer 102 may comprise a buried oxide (BOX) layer or SiGe, or another suitable material such as a III-V semiconductor epitaxial layer.

Isolation regions 104 (for example, shallow trench isolation (STI)) comprising dielectric material fill in recessed portions of the semiconductor substrate 101 between the nanosheet stacks of sacrificial layers 105 and the channel layers 107. A corresponding liner 108 is also formed between the isolation regions 104 and the semiconductor substrate 101. The liner 108 may be formed of SiN or another suitable material such as SiBCN, SiCOH, SiNCH, etc. The dielectric material may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), and combinations thereof.

A protective liner 115 is formed on sidewalls of the sacrificial layers 105 and the channel layers 107, and on the top surfaces of the uppermost sacrificial layers 105, as shown in FIG. 2C, for example. The protective liner 115 may be formed of SiN, SiO2, or another suitable material such as SiBCN, SiCOH, SiNCH, etc.

Inner spacers 113 are formed between portions of the top surface of the BDI layer 109, portions of the top and bottom surfaces of the MDI layer 110, and on sides of the stacked structures of the sacrificial layers 105 and the channel layers 107, as shown. The inner spacers 113 may be formed, for example, by exposing portions of the top surface of the BDI layer 109 on sides of the stacked structures of the sacrificial layers 105 and the channel layers 107 are exposed. Due to, for example, germanium in the sacrificial layers 105, lateral etching of the sacrificial layers 105 can be performed selective to the channel layers 107, such that the side portions of the sacrificial layers 105 can be removed to create vacant areas to be filled in by the inner spacers 113. The material of the inner spacers 113 can comprise, but is not necessarily limited to, a nitride, such as, SiN, SiON, SiCN, BN, SiBN, SiBCN or SiOCN.

Dummy gate portions 111 are formed on and around the protective liner 115 of the nanosheet stacks of the sacrificial layers 105 and channel layers 107. The dummy gate portions 111 include, but are not necessarily limited to, an amorphous silicon (a-Si) layer. The dummy gate portions 111 are formed using any suitable deposition techniques, such as chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD), followed by a planarization step, such as a chemical mechanical planarization (CMP) process.

Gate spacers 112 are positioned on the nanosheet stacks on opposite lateral sides of the dummy gate portions 111. In an illustrative embodiment, the gate spacers 112 are formed from the same or similar material to that of the inner spacers 113.

Hardmask (HM) layers 120 and 121 are formed on the dummy gate portions 111. The HM layer 120 can comprise, for example, a nitride layer such as SiN or other nitride material, and the HM layer 121 can comprise, for example, an oxide layer, such as SiO2 or other suitable oxide material.

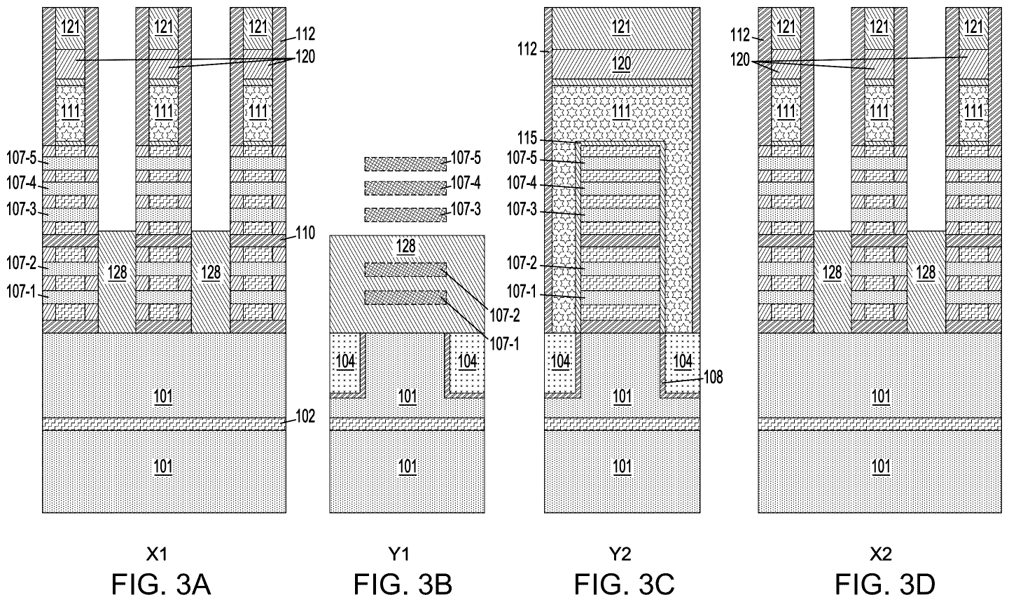

FIGS. 3A-3D show cross-sectional views, which respectively correspond to the lines X1, Y1, Y2, and X2 in FIG. 1, of the semiconductor structure 100 following formation of a dielectric protection layer 128, according to an illustrative embodiment. The dielectric protection layer 128 is formed by depositing dielectric material on exposed portions of the semiconductor substrate 101 between the nanosheet stacks of the sacrificial layers 105 and channel layers 107 and recessed down to a level corresponding to the top surface of the MDI layer 110, as shown in FIG. 3A, on portions of the semiconductor substrate 101, one portions of the isolation regions 104, and on and around the channel layers 107-1 and 107-2, as shown in FIG. 3B. In some embodiments, the dielectric material may comprise, for example, oxide and/or nitride materials such as SiN, a multi-layer of SiN and SiO2, or other suitable materials, and is deposited using deposition techniques such as, for example, CVD, PECVD, RFCVD, PVD, ALD, MBD, PLD, and/or LSMCD.

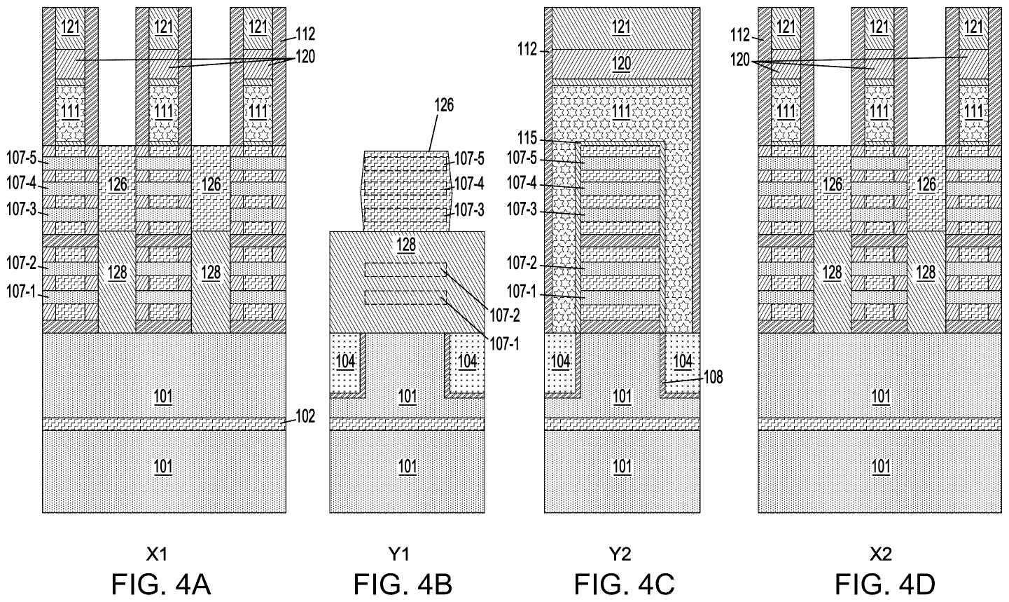

FIGS. 4A-4D show cross-sectional views, which respectively correspond to the lines X1, Y1, Y2, and X2 in FIG. 1, of the semiconductor structure 100 following formation of top source/drain regions 126, according to an illustrative embodiment. The top source/drain regions 126 are epitaxially grown from the exposed surfaces of the channel layers 107 and isolated from sacrificial layers 105 by the inner spacer 113.

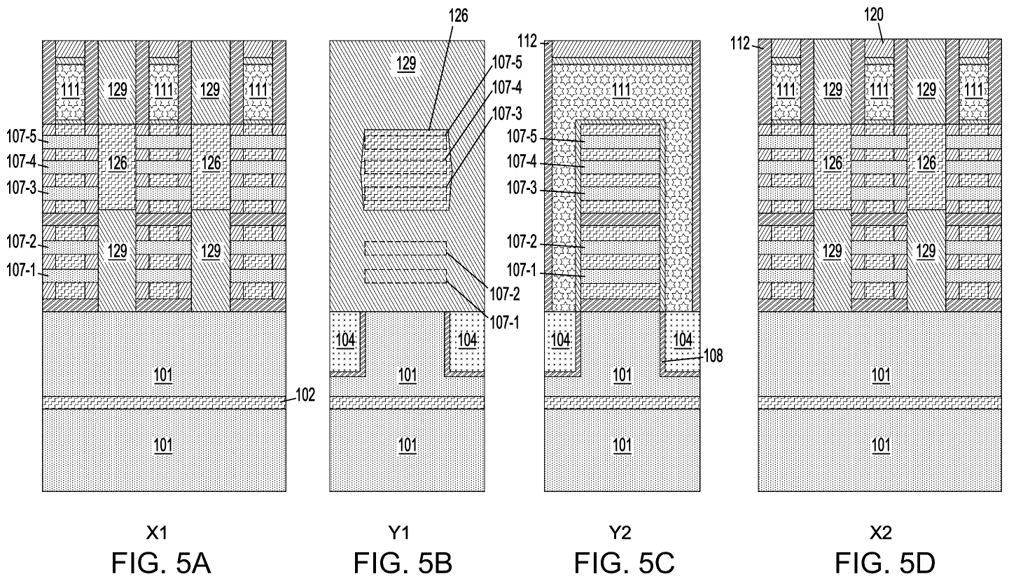

FIGS. 5A-5D show cross-sectional views, which respectively correspond to the lines X1, Y1, Y2, and X2 in FIG. 1, of the semiconductor structure 100 following a dielectric fill process, according to an illustrative embodiment. Specifically, dielectric material is deposited on the top surface of the dielectric protection layer 128 to fill in portions on and around the source/drain regions 126, thereby forming a frontside interlayer dielectric (ILD) layer 129. The dielectric material can be deposited using deposition techniques such as, for example, CVD, PECVD, RFCVD, PVD, ALD, MBD, PLD, and/or LSMCD, followed by a planarization process, such as, a poly open CMP (POC) process, to remove excess portions of the frontside ILD layer 129 deposited on top of the HM layer 121 and gate spacers 112, and to remove the HM layer 121, portions of the HM layer 120, and portions of gate spacers 112, as shown in FIGS. 5A and 5C, and 5D.

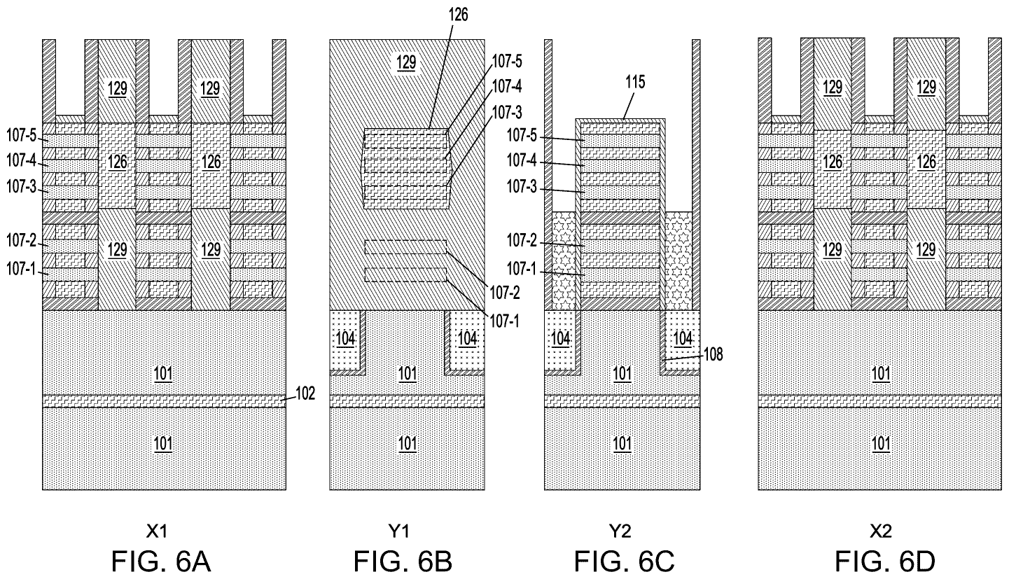

FIGS. 6A-6D show cross-sectional views, which respectively correspond to the lines X1, Y1, Y2, and X2 in FIG. 1, of the semiconductor structure 100 following partial removal of dummy gate portions 111, according to an illustrative embodiment. For example, hot ammonia can be used to remove a-Si corresponding to parts of the dummy gate portions 111, top and side surfaces of the protective liner 115 adjacent to the sacrificial layers 105-4, 105-5, and 105-6 and channel layers 107-3, 107-4, and 107-5.

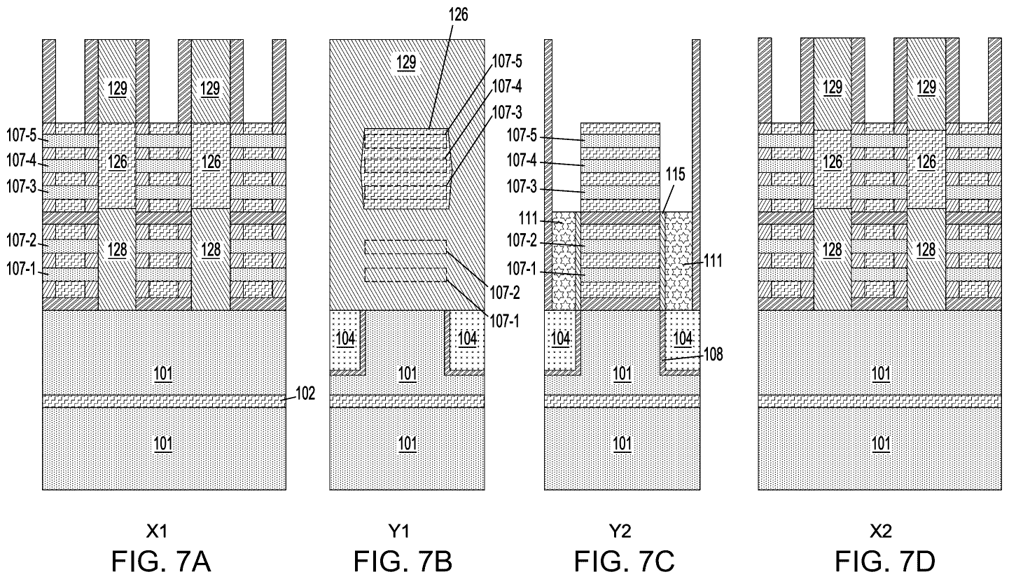

FIGS. 7A-7D show cross-sectional views, which respectively correspond to the lines X1, Y1, Y2, and X2 in FIG. 1, of the semiconductor structure 100 following etching of the protective liner 115, according to an illustrative embodiment. The exposed portions of the protective liner 115 may be removed using any suitable etch process, such as atomic layer etching (ALE), isotropic etching, etc.

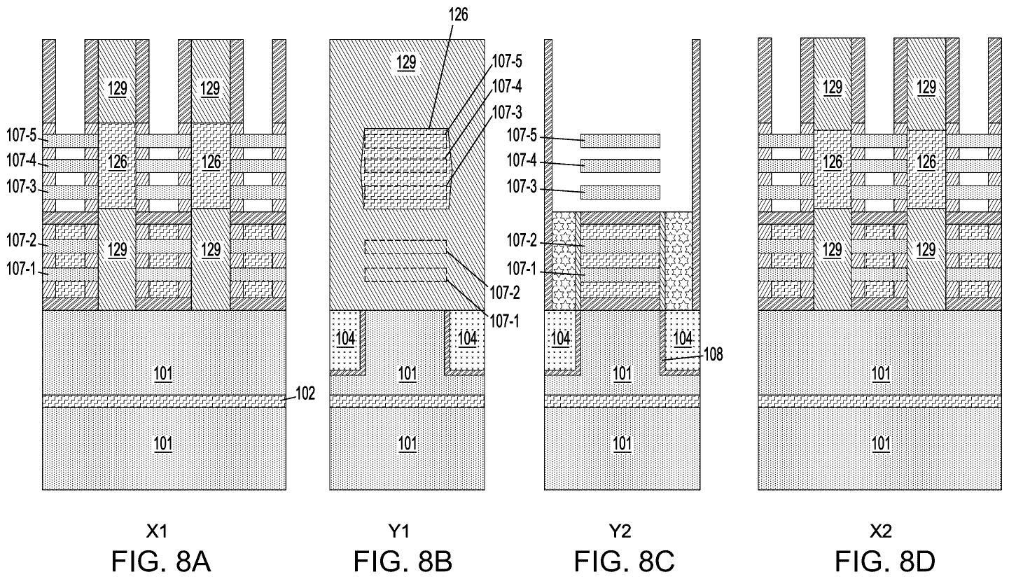

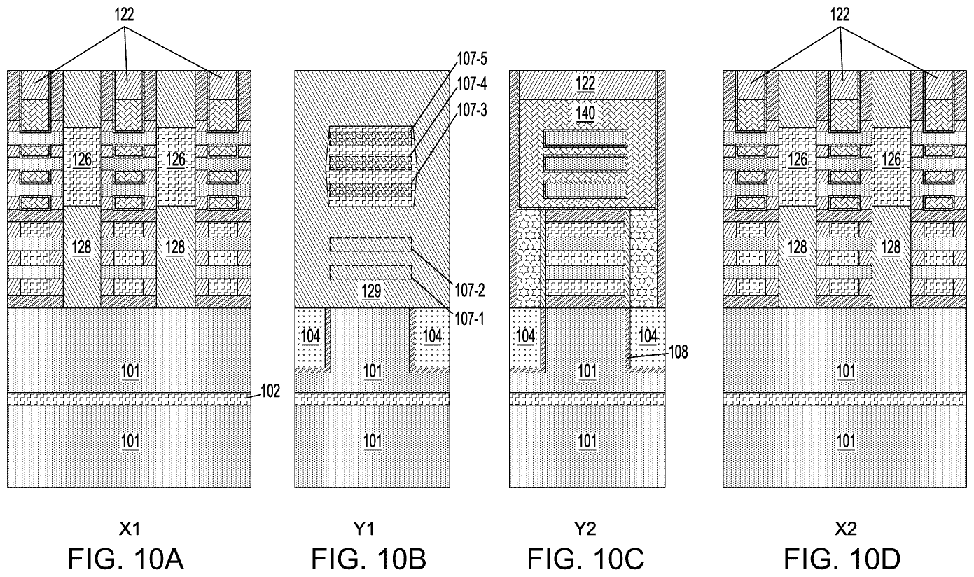

FIGS. 8A-8D show cross-sectional views, which respectively correspond to the lines X1, Y1, Y2, and X2 in FIG. 1, of the semiconductor structure 100 following removal of sacrificial layers 105-4, 105-5, and 105-6, according to an illustrative embodiment. The sacrificial layers 105-4, 105-5, and 105-6 can be selectively removed to create vacant areas in which gate regions or structures will be formed, as described in more detail in conjunction with FIGS. 10A-10D. The sacrificial layers 105-4, 105-5, and 105-6 can be selectively removed with respect to the channel layers 107 using, for example, a dry HCl etch.

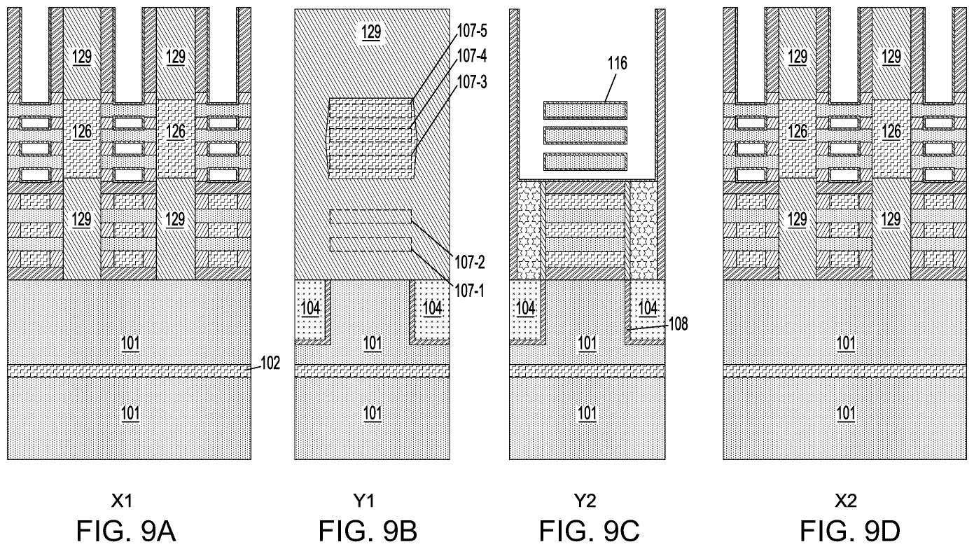

FIGS. 9A-9D show cross-sectional views, which respectively correspond to the lines X1, Y1, Y2, and X2 in FIG. 1, of the semiconductor structure 100 following formation of a top gate high-K metal gate (HKMG) structure 116, according to an illustrative embodiment. The top gate HKMG structure 116 can be formed using conformal deposition of a dielectric material that is deposited over exposed vertical and horizontal surfaces of the channel layers 107-3, 107-4, and 107-5, the dummy gate portions 111, and the protective liner 115. In illustrative embodiments, the top gate HKMG structure 116 can be formed of, for example, a HK dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of HK materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the top gate HKMG structure 116 can also include a WFM layer deposited on the exposed surfaces of the HK dielectric layer. The WFM layer can include, but is not necessarily limited to, for a pFET, titanium nitride (TiN), tantalum nitride (TaN) or ruthenium (Ru), and for an nFET, TiN, titanium aluminum nitride (TiAIlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN.

FIGS. 10A-10D show cross-sectional views, which respectively correspond to the lines X1, Y1, Y2, and X2 in FIG. 1, of the semiconductor structure 100 following formation of a top metal gate layer 140 and a self-aligned contact (SAC) cap layer 122, according to an illustrative embodiment. The top metal gate layer 140 can be formed in the vacant portions left by the removal of the dummy gate portions 111 and the sacrificial layers 105-4, 105-5, and 105-6. The material of the top metal gate layer 140 can include, but is not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the top gate HKMG structure 116. The SAC cap layer 122 can comprise, for example, silicone for example, silicon nitride or some other suitable capping layer material. In some embodiments, the SAC cap layer 122 can be a similar material to the gate spacers 112, for example.

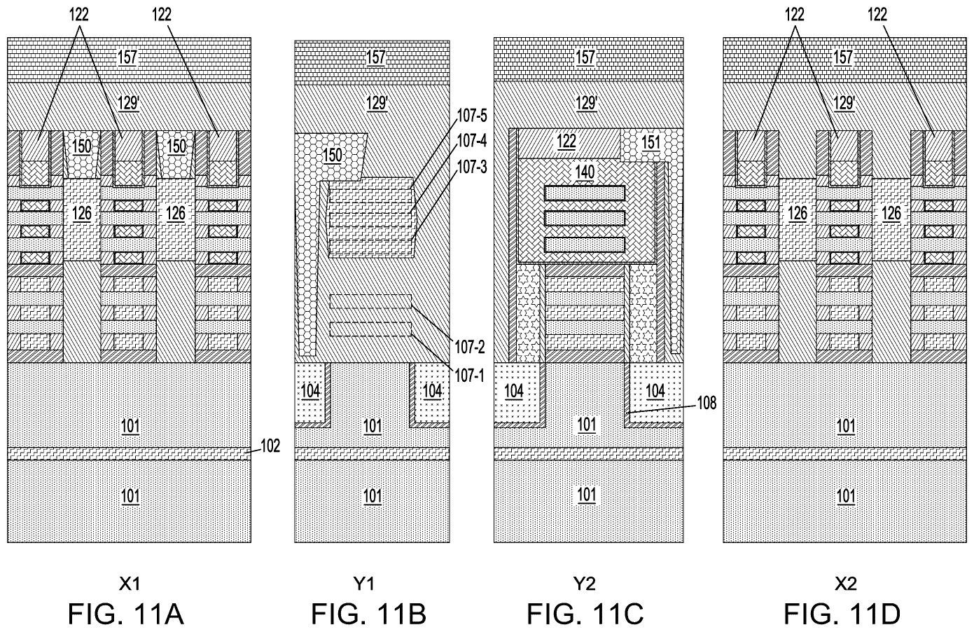

FIGS. 11A-11D show cross-sectional views, which respectively correspond to the lines X1, Y1, Y2, and X2 in FIG. 1, of the semiconductor structure 100 following frontside contact formation and carrier wafer bonding, according to an illustrative embodiment. The formation of the frontside contacts and the carrier wafer bonding can include depositing additional dielectric material on top of the frontside ILD layer 129, the gate spacers 112, and the top metal gate layer 140 to form frontside ILD layer 129′, and forming frontside source/drain contacts 150, at least one gate contact 151, and bonding of the structure (e.g., the frontside ILD layer 129′) to a carrier wafer 157. The frontside source/drain contacts 150 can be formed in the frontside ILD layer 129′ to contact corresponding top surfaces of the source/drain regions 126. In forming the frontside source/drain contacts 150, openings are formed through portions of the frontside ILD layer 129′. The openings expose at least portions of the source/drain regions 126 on which the frontside source/drain contacts 150 are formed. Forming the frontside source/drain contacts 150 can also include forming deep vias that extend through the frontside ILD layer 129′ towards top surfaces of the isolation regions 104, as shown in FIGS. 11B and 11C.

In forming the frontside source/drain contacts 150, openings are formed through portions of the frontside ILD layer 129′. The openings expose at least portions of the source/drain regions 126 on which the frontside source/drain contacts 150 are formed.

According to an embodiment, masks can be formed on portions of the frontside ILD layer 129′, and exposed portions of the frontside ILD layer 129′ corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers are deposited in the openings to form the frontside source/drain contacts 150. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the frontside ILD layer 129′. The frontside source/drain contacts 150 land on and contact the source/drain regions 126.

In some embodiments, the gate contact 151 is formed through the frontside ILD layer 129′ to land on and contact one or more corresponding portions of the top metal gate layer 140, as shown in FIG. 11C, for example. The process and materials used for forming the gate contact 151 are similar to those used for forming the frontside source/drain contacts 150.

The carrier wafer 157 may be formed of materials similar to that of the semiconductor substrate 101 and may be formed over the frontside ILD layer 129′ using a wafer bonding process, such as dielectric-to-dielectric bonding.

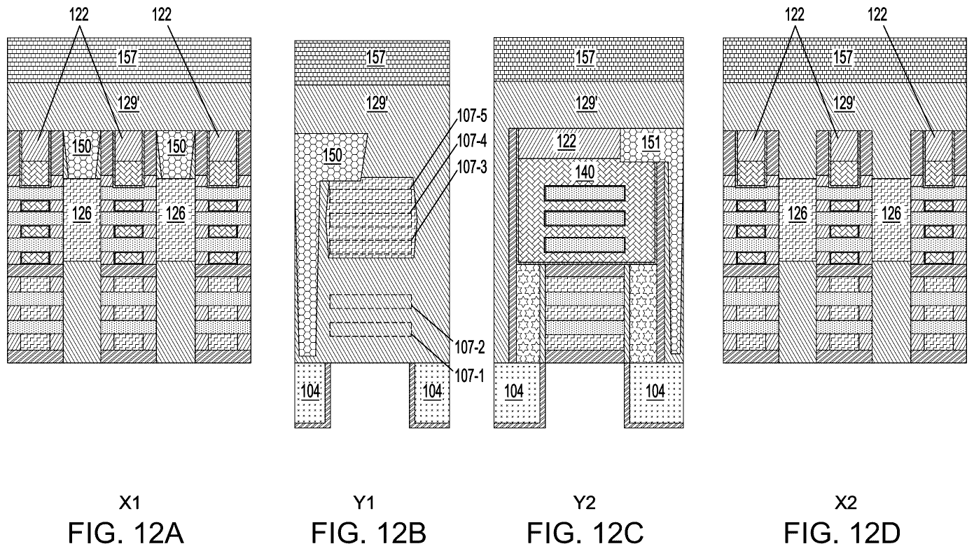

FIGS. 12A-12D show cross-sectional views, which respectively correspond to the lines X1, Y1, Y2, and X2 in FIG. 1, of the semiconductor structure 100 following wafer flipping and semiconductor substrate 101 removal, according to an illustrative embodiment. For example, using the carrier wafer 157, the semiconductor structure 100 may be “flipped” (for example, rotated 180 degrees) so that the structure is inverted. Additionally, the semiconductor substrate 101, is removed from the backside of the semiconductor structure 100. The removal process can include, for example, etching the semiconductor layer with an etchant that selectively etches silicon with respect to a material of the etch stop layer 102. The etch stop layer 102 and the remaining semiconductor substrate 101 are then removed. The etching process for removal of the etch stop layer 102 can include, for example, IBE by Ar/CHF3 based chemistry. Etchants for removing the semiconductor substrate 101 include, for example, KOH and TMAH.

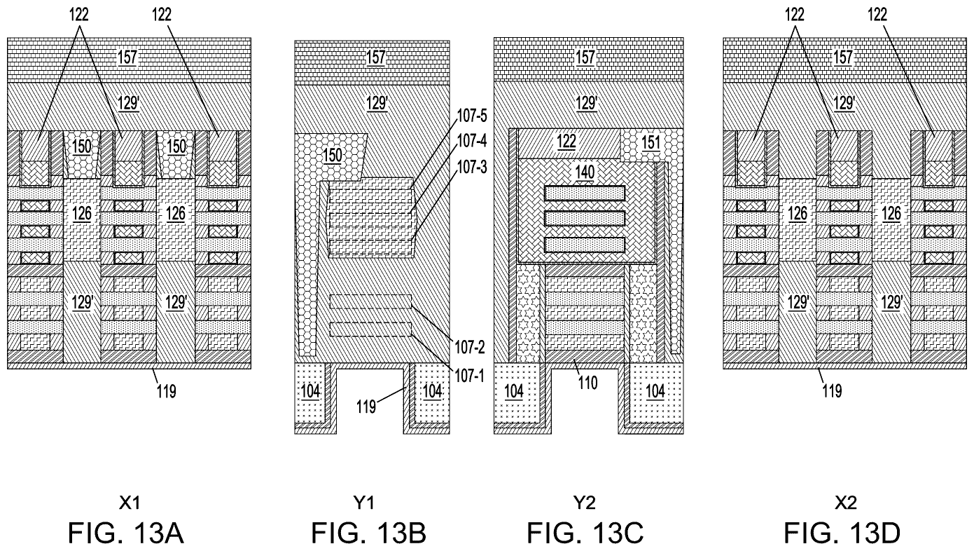

FIGS. 13A-13D show cross-sectional views, which respectively correspond to the lines X1, Y1, Y2, and X2 in FIG. 1, of the semiconductor structure 100 following formation of a dielectric liner 119, according to an illustrative embodiment. The dielectric liner 119 is formed on the exposed horizontal and vertical surfaces of the liner 108, the BDI layer 109, and the bottom surface of the frontside ILD layer 129′. The material of the dielectric liner 119 can comprise, but is not necessarily limited to, a nitride, such as, SiN, SiON, SiCN, BN, SiBN, SiBCN or SiOCN.

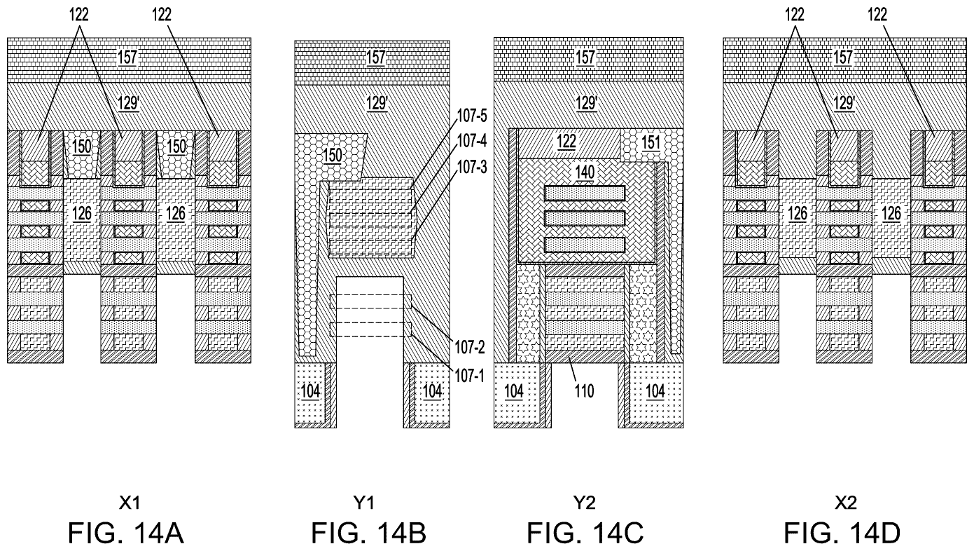

FIGS. 14A-14D show cross-sectional views, which respectively correspond to the lines X1, Y1, Y2, and X2 in FIG. 1, of the semiconductor structure 100 following recessing of the dielectric liner 119 and a self-aligned selective etch of the frontside ILD layer 129′, according to an illustrative embodiment. Removing the horizontal surfaces of the liner 119 and the portions of the frontside ILD layer 129′ can include using, for example, a dry etching process using a RIE or IBE process, a wet chemical etching process or a combination of these etching processes. A dry etch may be performed using a plasma. Such wet or dry etch processes include, for example, IBE by Ar/CHF3 based chemistry. For example, in FIGS. 14A-14D, portions of the frontside ILD layer 129′ below the source/drain regions 126 are removed up to a level corresponding to the MDI layer 110.

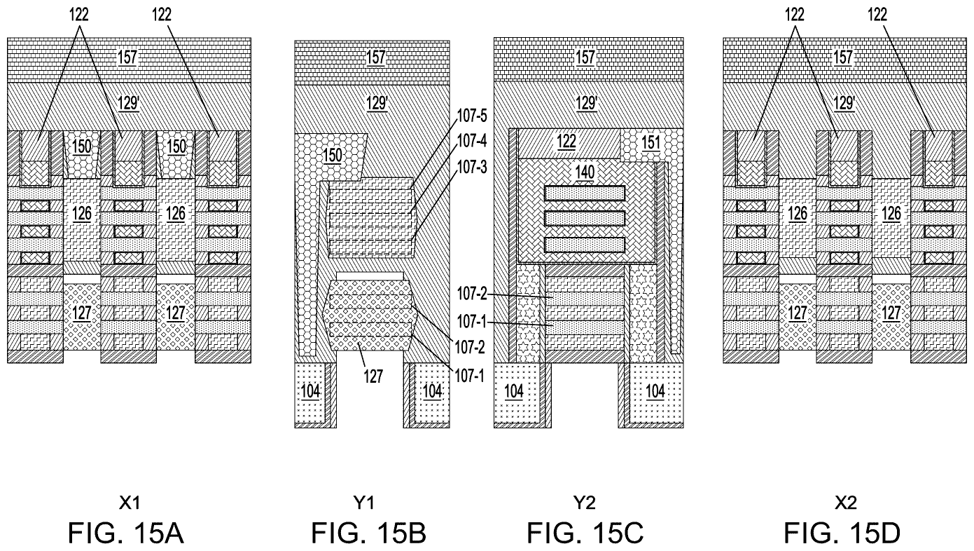

FIGS. 15A-15D show cross-sectional views, which respectively correspond to the lines X1, Y1, Y2, and X2 in FIG. 1, of the semiconductor structure 100 following bottom source/drain region formation, according to an illustrative embodiment. The bottom source/drain regions 127 can be formed in a similar manner as the top source/drain regions 126, for example.

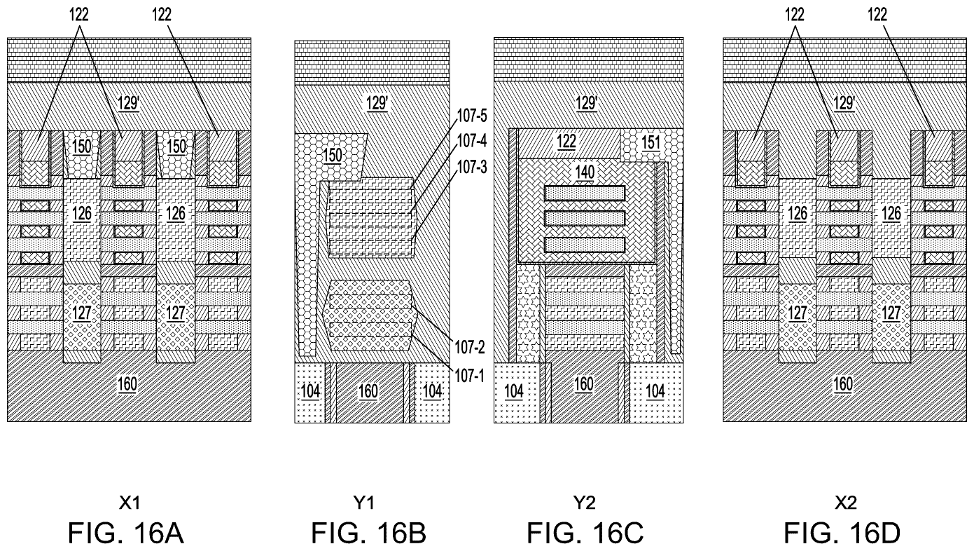

FIGS. 16A-16D show cross-sectional views, which respectively correspond to the lines X1, Y1, Y2, and X2 in FIG. 1, of the semiconductor structure 100 following backside dielectric fill and recess, according to an illustrative embodiment. More specifically, dielectric material is deposited to fill in portions on and around the bottom source/drain regions 127, and to form backside dielectric layer 160. The dielectric material can be deposited using deposition techniques such as, for example, CVD, PECVD, RFCVD, PVD, ALD, MBD, PLD, and/or LSMCD. The dielectric material of the backside dielectric layer 160 may comprise, but is not necessarily limited to, a nitride, such as, SiN, SiON, SiCN, BN, SiBN, SiBCN or SiOCN. The backside dielectric fill can be followed by a planarization process, such as a CMP process. The liner 108 is also recessed to expose the bottom portions of the isolation regions 104. The liner 108 can be recessed, for example, using any suitable etch process, such as atomic layer etching (ALE), isotropic etching, etc.

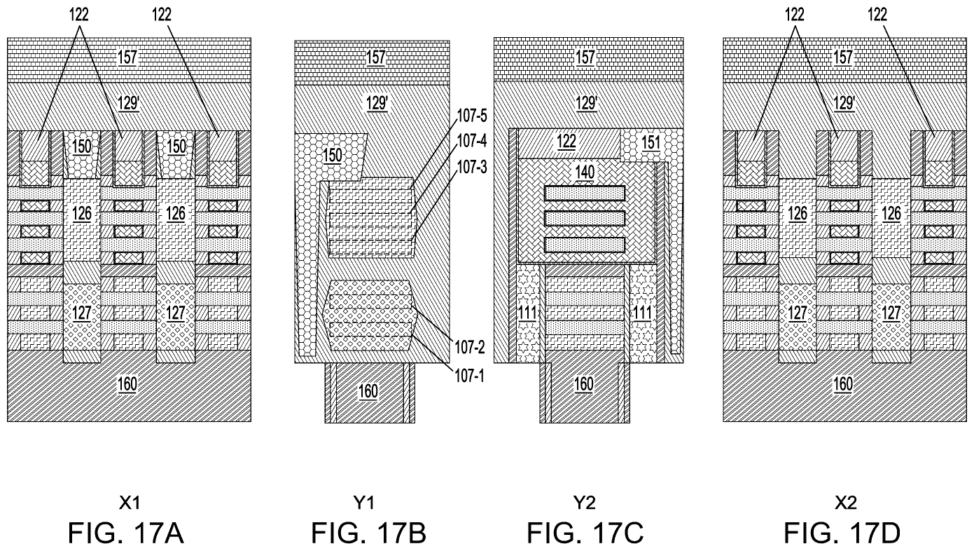

FIGS. 17A-17D show cross-sectional views, which respectively correspond to the lines X1, Y1, Y2, and X2 in FIG. 1, of the semiconductor structure 100 following recessing of the isolation regions 104, according to an illustrative embodiment. The isolation regions 104 can be recessed to expose the bottom surfaces of the dummy gate portions 111 using, for example, a dry etching process using a RIE or IBE process, a wet chemical etching process or a combination of these etching processes.

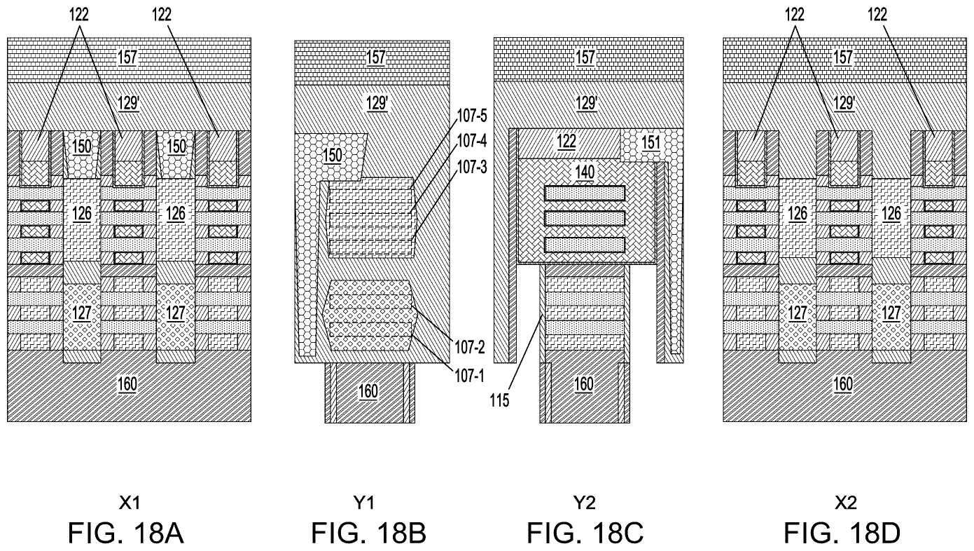

FIGS. 18A-18D show cross-sectional views, which respectively correspond to the lines X1, Y1, Y2, and X2 in FIG. 1, of the semiconductor structure 100 following removal of the remaining dummy gate portions 111, according to an illustrative embodiment. The remaining dummy gate portions 111 can be removed using hot ammonia, for example.

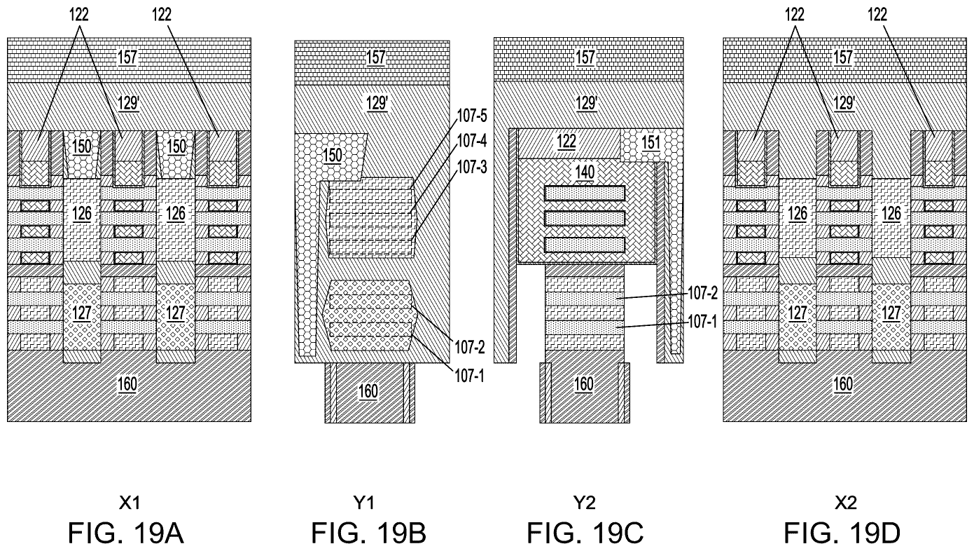

FIGS. 19A-19D show cross-sectional views, which respectively correspond to the lines X1, Y1, Y2, and X2 in FIG. 1, of the semiconductor structure 100 following etching of the protective liner 115, according to an illustrative embodiment. The exposed portions of the protective liner 115 may be removed using any suitable etch process, such as ALE, isotropic etching, etc.

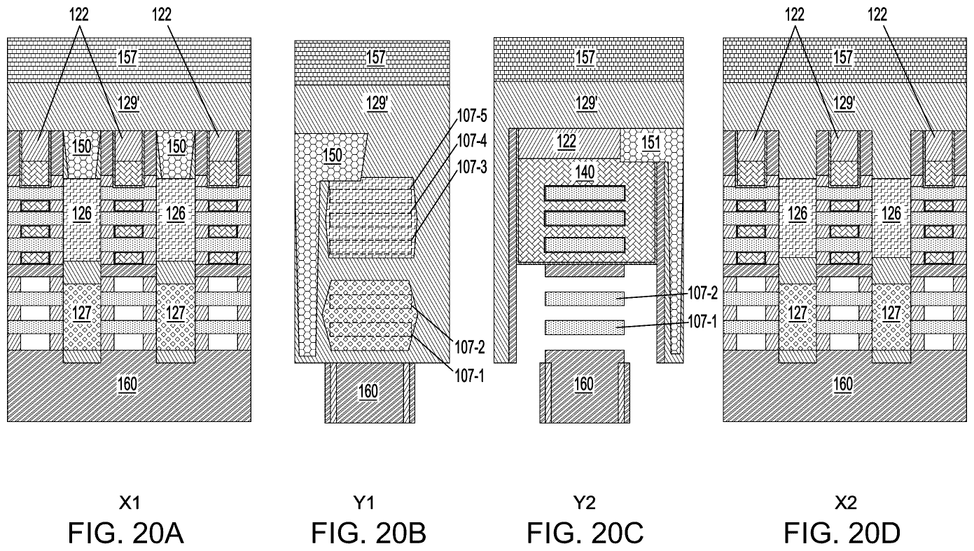

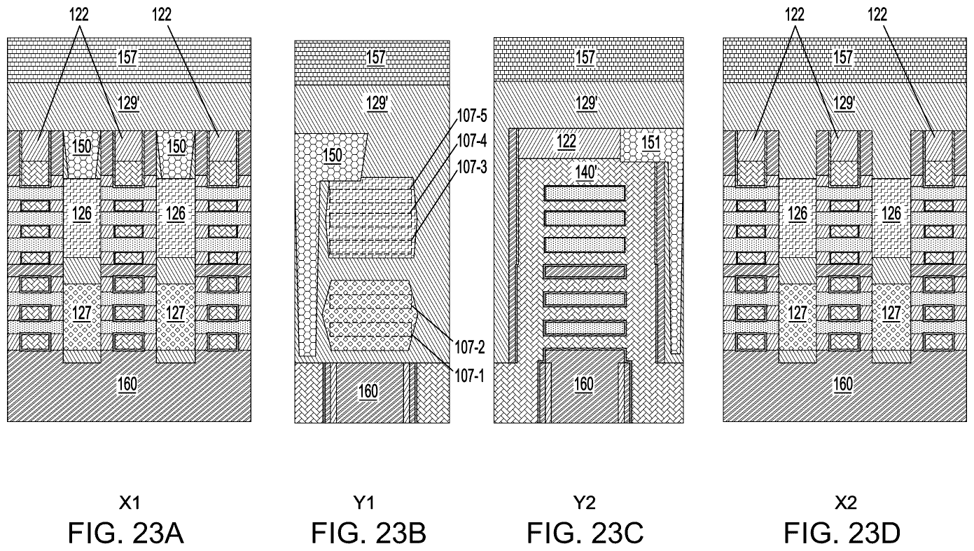

FIGS. 20A-20D show cross-sectional views, which respectively correspond to the lines X1, Y1, Y2, and X2 in FIG. 1, of the semiconductor structure 100 following removal of sacrificial layers 105-1, 105-2, and 105-3, according to an illustrative embodiment. The sacrificial layers 105-1, 105-2, and 105-3 can be removed using similar techniques as described with respect to sacrificial layers 105-4, 105-5, and 105-6 to create vacant areas, in which gate regions or structures will be formed, as described in more detail in conjunction with FIGS. 23A-23D.

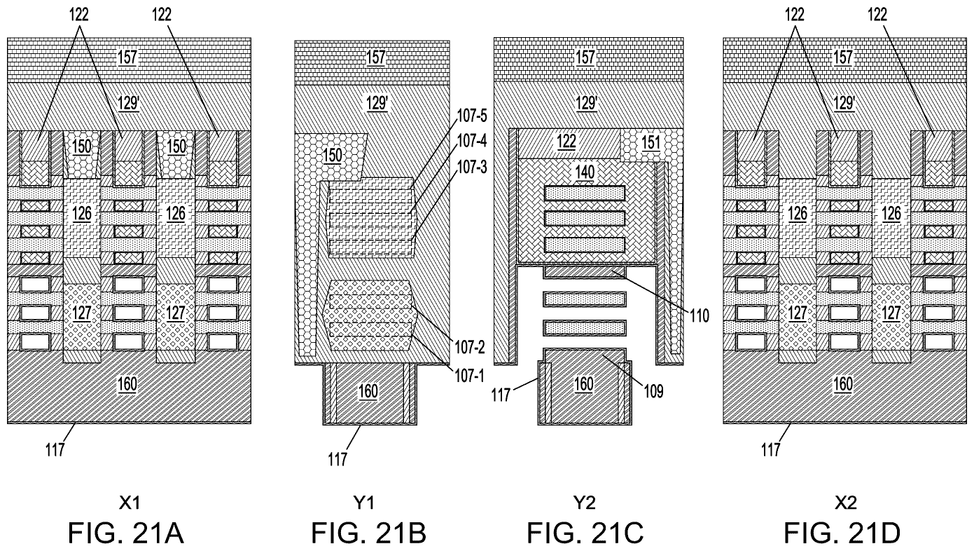

FIGS. 21A-21D show cross-sectional views, which respectively correspond to the lines X1, Y1, Y2, and X2 in FIG. 1, of the semiconductor structure 100 following formation of a bottom gate HKMG structure 117, according to an illustrative embodiment. The bottom gate HKMG structure 117 can be formed using similar materials and techniques as described above for the top gate HKMG structure 116, for example. Specifically, the bottom gate HKMG structure 117 is formed on the exposed horizontal and vertical surfaces, including the surfaces of the channel layers 107-1 and 107-2, the backside dielectric layer 160, the frontside ILD layer 129, the BDI layer 109 and the MDI layer 110. In some embodiments, the WFM layer of the bottom gate HKMG structure 117 is a different material than the WFM layer of the top gate HKMG structure 116.

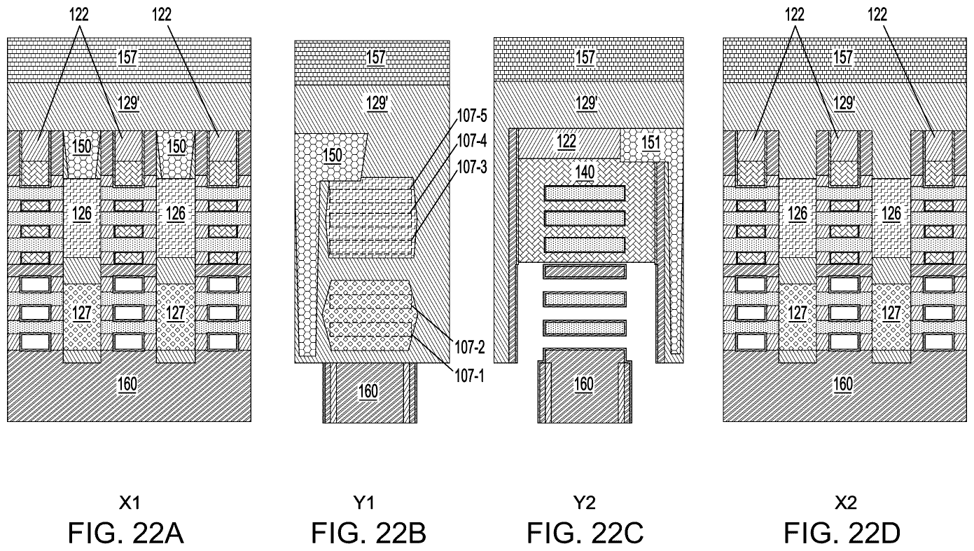

FIGS. 22A-22D show cross-sectional views, which respectively correspond to the lines X1, Y1, Y2, and X2 in FIG. 1, of the semiconductor structure 100 following recessing of the top and bottom HKMG structures 116 and 117, according to an illustrative embodiment. The recessing can include removing portions of the bottom gate HKMG structure 117 and portions of the top gate HKMG structure 116 from the bottom surface of the top metal gate layer 140, as shown.

FIGS. 23A-23D show cross-sectional views, which respectively correspond to the lines X1, Y1, Y2, and X2 in FIG. 1, of the semiconductor structure 100 following formation of a bottom metal gate layer to form metal gate layer 140′ comprising a continuous metal fill (e.g., such as tungsten or another suitable conductive material), according to an illustrative embodiment. The metal gate layer 140′ can be formed (e.g., using a replacement metal gate process) in the vacant portions left by the removal of the dummy gate portions 111, the isolation regions 104, and the sacrificial layers 105-1 and 105-2.

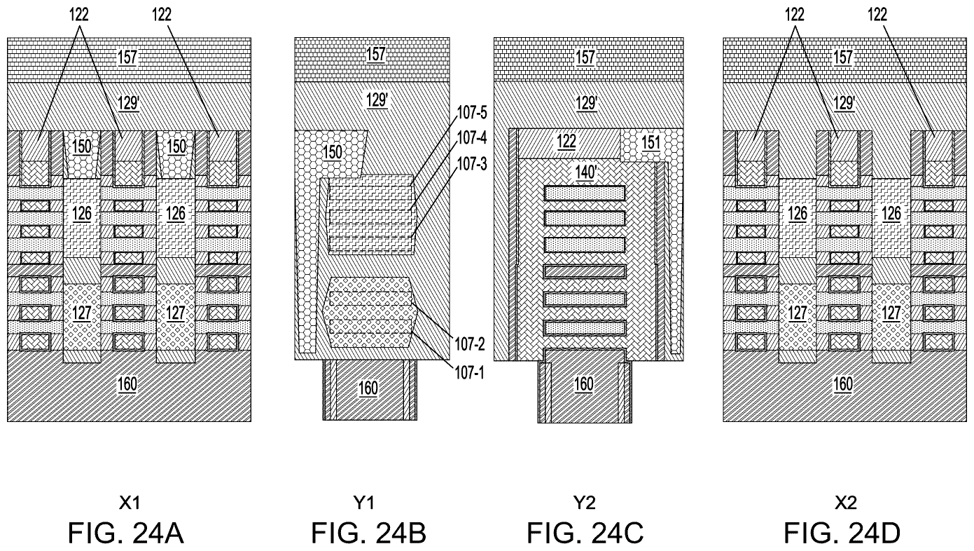

FIGS. 24A-24D show cross-sectional views, which respectively correspond to the lines X1, Y1, Y2, and X2 in FIG. 1, of the semiconductor structure 100 following recessing of the metal gate layer 140′, according to an illustrative embodiment. The metal gate layer 140′ can be recessed using hot ammonia, for example, to remove the portions of the metal gate layer 140′ where the isolation regions 104 were previously located.

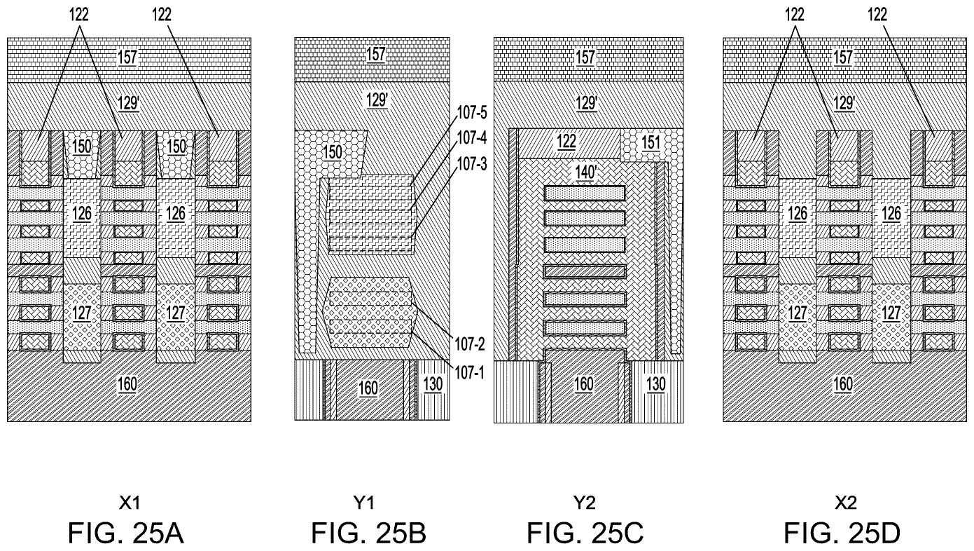

FIGS. 25A-25E show cross-sectional views, which respectively correspond to the lines X1, Y1, Y2, and X2 in FIG. 1, of the semiconductor structure 100 following backside dielectric fill, according to an illustrative embodiment. The backside dielectric fill includes filling the vacant portions resulting from the recessing of the metal gate layer 140′ with a dielectric material to form a backside ILD layer 130. In some embodiments, the backside ILD layer 130 can be formed using a similar process and materials as the frontside ILD layer 129, for example.

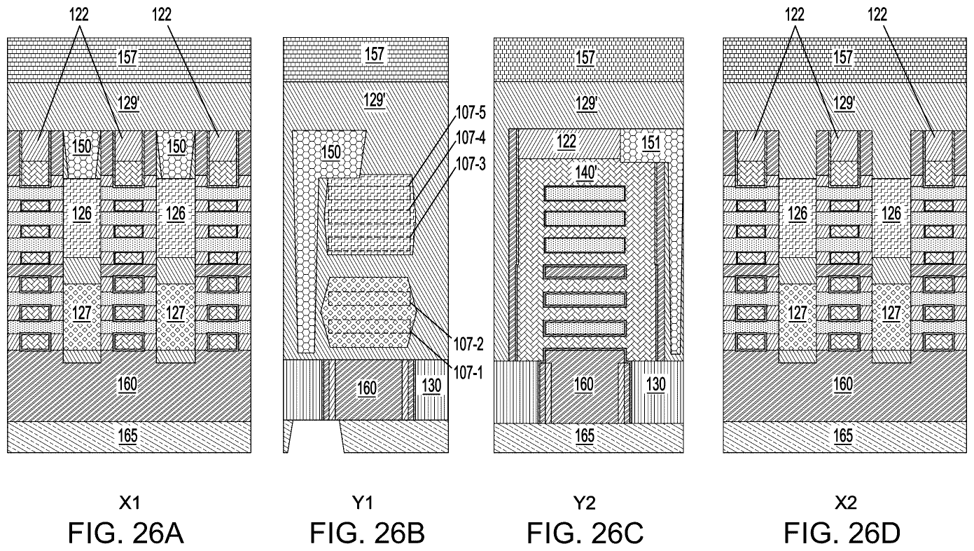

FIGS. 26A-26D show cross-sectional views, which respectively correspond to the lines X1, Y1, Y2, and X2 in FIG. 1, of the semiconductor structure 100 following backside contact patterning, according to an illustrative embodiment. The backside contact layer patterning can include depositing an organic planarization layer (OPL) 165 on the bottom surface of the semiconductor structure. The OPL 165 can be formed of an organic polymer such as C, H, and/or N. Openings in the OPL 165 shown in FIG. 26B correspond to areas where the backside ILD layer 130 is to be recessed.

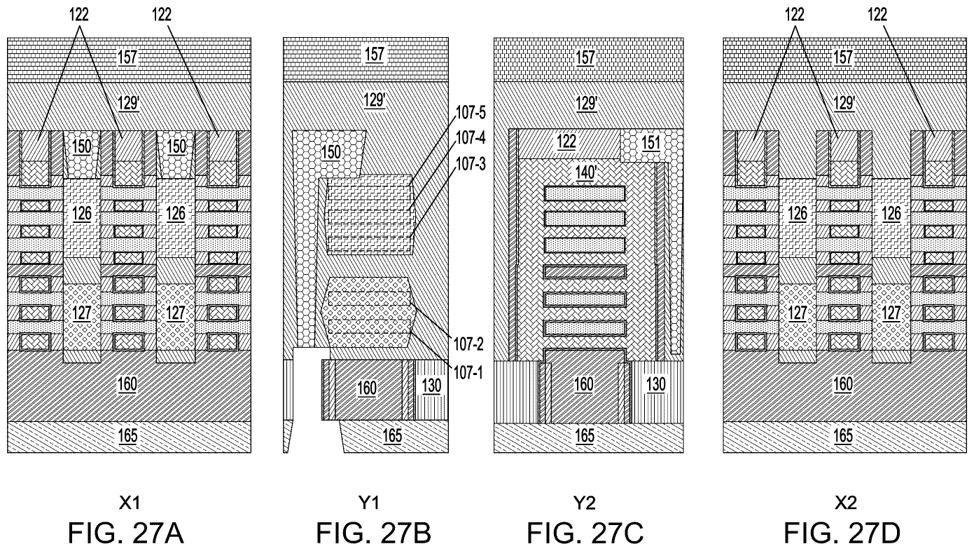

FIGS. 27A-27D show cross-sectional views, which respectively correspond to the lines X1, Y1, Y2, and X2 in FIG. 1, of the semiconductor structure 100 following selective self-aligned recess of the backside ILD layer 130 and frontside ILD layer 129′, according to an illustrative embodiment. The selective self-aligned recess can include recessing the backside ILD layer 130 and the frontside ILD layer 129′ in the portions above the openings in the OPL 165. For example, the recessing can include selectively removing the exposed portions of the backside ILD layer 130 and the frontside ILD layer 129′ using, for example, a dry etching process using an RIE or an IBE process, a wet chemical etching process or a combination of these etching processes. For example, in FIG. 27B, exposed portions of the backside ILD layer 130 and the frontside ILD layer 129′ are removed to expose the bottom surface of the corresponding frontside source/drain contacts 150.

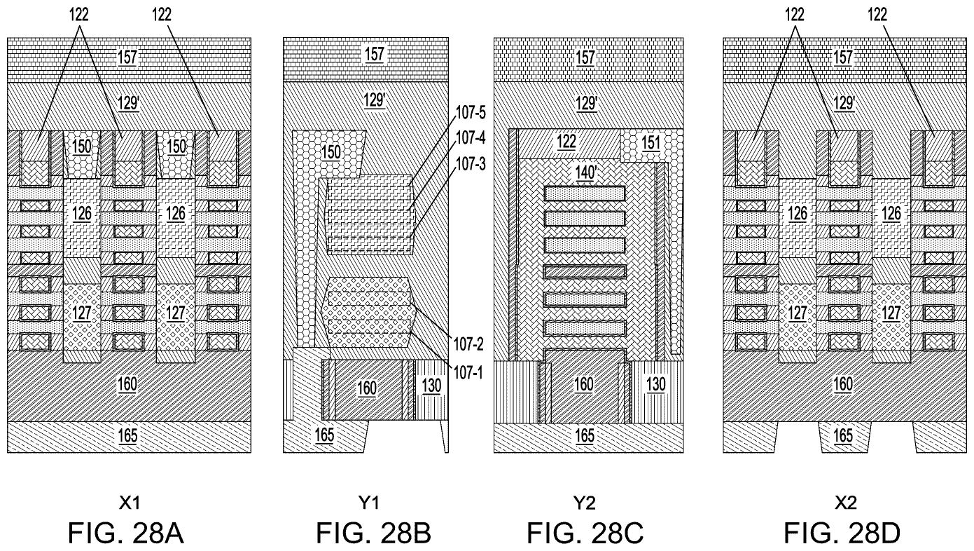

FIGS. 28A-28D show cross-sectional views, which respectively correspond to the lines X1, Y1, Y2, and X2 in FIG. 1, of the semiconductor structure 100 following source contact patterning for the bottom device and drain contact patterning for the top device, according to an illustrative embodiment. The source contact patterning can be performed using similar techniques as the backside contact layer patterning. In this example, openings in the OPL 165 are formed at least partially under the bottom source/drain regions 127, as shown in FIGS. 28B and 28D.

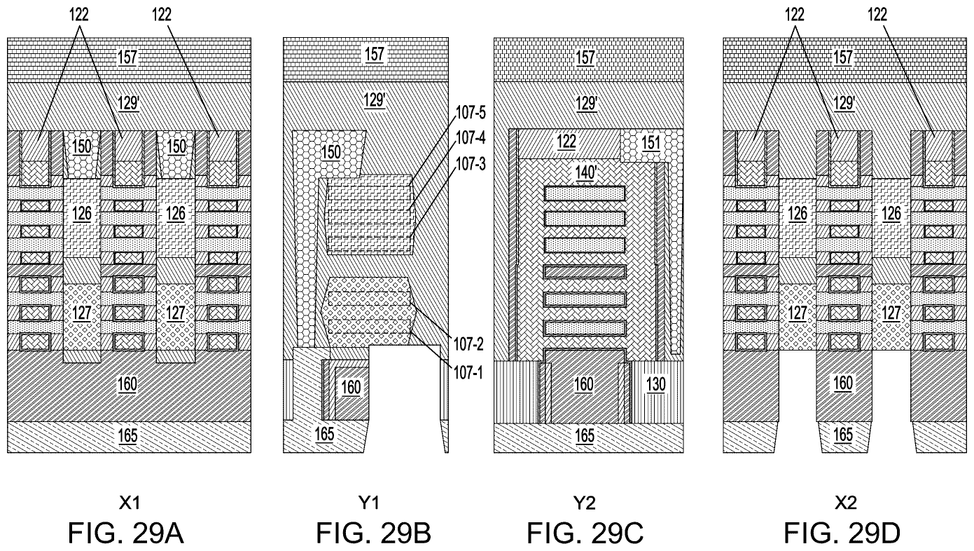

FIGS. 29A-29D show cross-sectional views, which respectively correspond to the lines X1, Y1, Y2, and X2 in FIG. 1, of the semiconductor structure 100 following recessing for a bottom source contact and for a top drain contact, according to an illustrative embodiment. In this example, the material between the openings of the OPL 165 and the portions of the bottom source/drain regions 127 shown in FIG. 29D are removed (including the material corresponding to the backside dielectric layer 160, the backside ILD layer 130, and the liners 108 and 119) to expose the bottom surfaces of the bottom source/drain regions 127. The recessing can be performed in a similar manner as described in conjunction with FIGS. 27A-27D, for example.

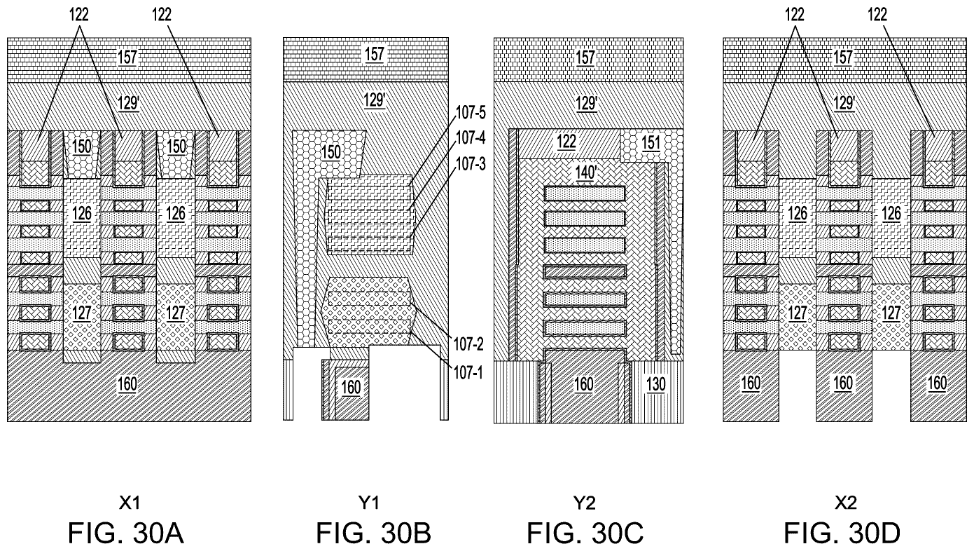

FIGS. 30A-30D show cross-sectional views, which respectively correspond to the lines X1, Y1, Y2, and X2 in FIG. 1, of the semiconductor structure 100 following OPL recessing, according to an illustrative embodiment. The OPL recessing can include removing the OPL 165 using, for example, a plasma stripping process.

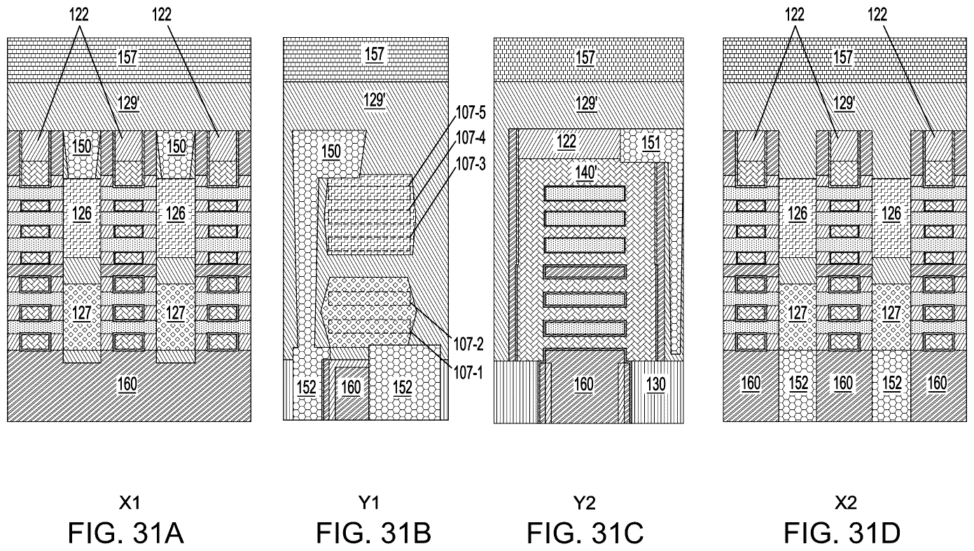

FIGS. 31A-31D show cross-sectional views, which respectively correspond to the lines X1, Y1, Y2, and X2 in FIG. 1, of the semiconductor structure 100 following backside contact metal fill and planarization, according to an illustrative embodiment. Backside source/drain contacts 152 are formed by fill and planarization of contact material. The contact material of the backside source/drain contacts 152 can be similar to that of the frontside source/drain contacts 150, for example. The backside source/drain contacts 152 shown in FIG. 31B contact bottom portions of the frontside source/drain contact 150 and the source/drain region 127, respectively. The backside source/drain contacts 152 shown in FIG. 31D contact corresponding bottom portions of the bottom source/drain regions 127.

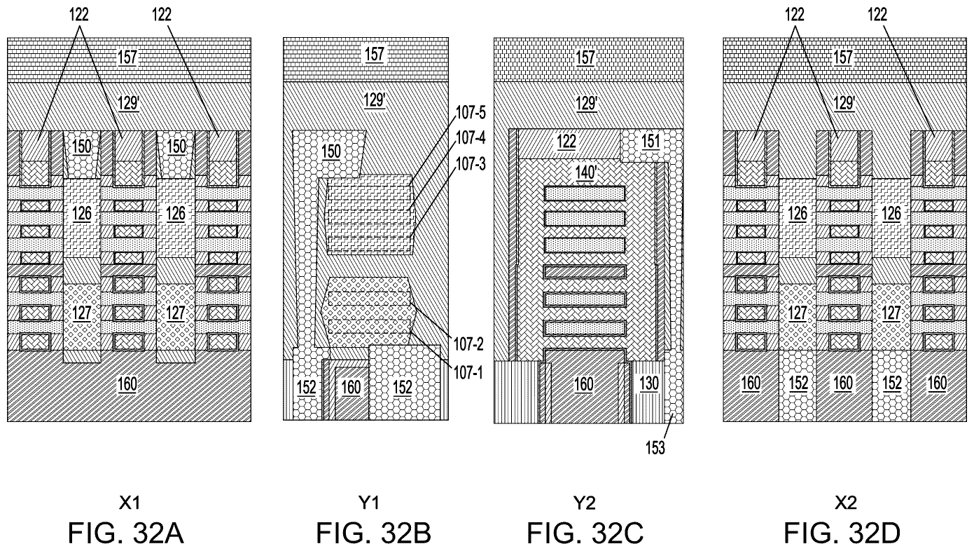

FIGS. 32A-32D show cross-sectional views, which respectively correspond to the lines X1, Y1, Y2, and X2 in FIG. 1, of the semiconductor structure 100 following gate interconnect formation, according to an illustrative embodiment. The gate interconnect formation includes forming a backside gate contact 153 that contacts the gate contact 151. The contact material of the backside source/drain contacts 152 may be similar to that of the frontside source/drain contact 150, for example.

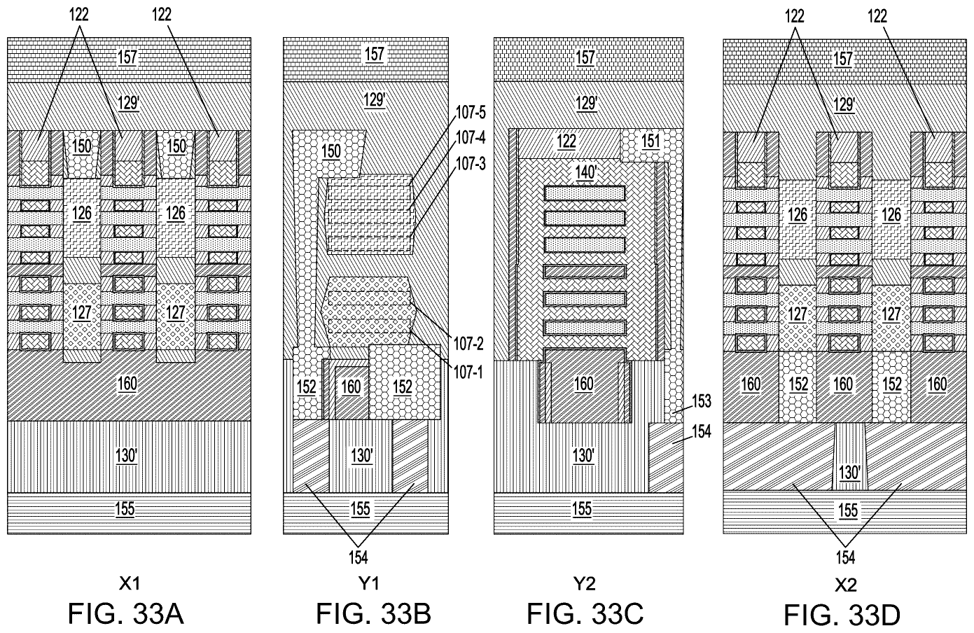

FIGS. 33A-33D show cross-sectional views, which respectively correspond to the lines X1, Y1, Y2, and X2 in FIG. 1, of the semiconductor structure 100 following backside interconnect formation. In some embodiments, additional dielectric material is can be deposited to form backside ILD layer 130′, and one or more metallization layers 154 can be formed through the backside ILD layer 130′ to connect the backside contacts 152 and 153 to backside BEOL layers 155 (also referred to herein as backside interconnects). For example, the backside BEOL layers 155 can be formed on the backside ILD layer 130′. The backside BEOL layers 155 can include various backside power delivery network structures such as, but not necessarily limited to, interconnects in a power supply path from voltage regulator modules (VRMs) to circuits. For example, FIG. 33B shows metallization layers 154 corresponding to a drain voltage (VDD) and source voltage (Vss). The interconnects can comprise, for example, power and ground planes in circuit boards, cables, connectors, and capacitors associated with a power supply. Backside power delivery prevents BEOL routing congestion, resulting in power performance benefits. The process and materials used for forming the metallization layers 154 can be similar to those used to form the backside source/drain contacts 152, for example.

Accordingly, at least some embodiments described herein can provide a semiconductor device that includes vertically stacked transistor devices with opposite polarity, HK-free regions where gate metal fill (e.g., corresponding to metal gate layer 140′) contacts dielectric material (e.g., 122 and 130′) on both the top and bottom surfaces, frontside and backside contacts, and interconnects on one side (e.g., backside BEOL layers 155). In some embodiments, an nFET device may be positioned on one side of the semiconductor device and a pFET device on the other side, where associated source/drain regions are vertically isolated by a dielectric barrier (e.g., corresponding to the portion of the frontside ILD layer 129′ between source/drain regions 126 and 127). HK materials, matched to the top transistor device, can line the gate spacer and inner spacer sides adjacent to the top transistor device. HK materials, matched to a bottom transistor device, line these components for the bottom transistor device as well as along a BDI layer (e.g., BDI layer 109). The gates can be self-aligned with continuous gate fill metal between the top and bottom FETs.

In an illustrative embodiment, a semiconductor device includes at least one stacked device structure including at least one upper transistor device including one or more upper channel layers, and at least one lower transistor device including one or more lower channel layers, and at least two high-k free dielectric layers. The semiconductor device also includes a common gate structure including a metal fill portion, where a first side of the metal fill portion contacts a first one of the at least two high-k free dielectric layers, and a second side of the metal fill portion contacts a second one of the at least two high-k free dielectric layers.

In embodiments, the at least one upper transistor device and the at least one lower transistor device may have opposing polarities.

In embodiments, the common gate structure further may include a first work function metal layer associated with the at least one upper transistor device and a second work function metal layer associated with the at least one lower transistor device, where the first work function metal layer comprises a different material than the second work function metal layer.

In embodiments, the semiconductor device may further include a first source/drain region that contacts the one or more upper channel layers, and a second source/drain region that contacts the one or more lower channel layers.

In embodiments, the semiconductor device may include a dielectric barrier disposed between the first source/drain region and the second source/drain region.

In embodiments, the semiconductor device may include a backside interconnect layer, one or more frontside contacts connected to the first source/drain region and the backside interconnect layer, and one or more backside contacts connected to the second source/drain region and the backside interconnect layer.

In embodiments, the at least one upper transistor device may include one of an n-type transistor device and a p-type transistor device, and the at least one lower transistor device including the other one of the n-type transistor device and the p-type transistor device.

In embodiments, the metal fill portion of the common gate structure may be continuous between the at least one upper transistor device and the at least one lower transistor device.

In another illustrative embodiment, a semiconductor device a semiconductor device includes at least one stacked transistor structure including at least one n-type transistor device and at least one p-type transistor device adjacent to the least one n-type transistor device, at least two high-k free dielectric layers, and a common gate structure. The common gate structure includes a continuous metal fill portion, where a bottom surface of the continuous metal fill portion directly contacts a first one of the at least two high-k free dielectric layers, and a top surface of the continuous metal fill portion directly contacts a second one of the at least two high-k free dielectric layers.

In embodiments, the at least one n-type transistor device and the at least one p-type transistor device may have opposing polarities.

In embodiments, the common gate structure may include a first work function metal layer associated with the n-type transistor device and a second work function metal layer associated with the p-type transistor device, wherein the first work function metal layer includes a different material than the second work function metal layer.

In embodiments, the common gate structure may include a first high-k dielectric layer, where the first work function metal layer is disposed between the first high-k dielectric layer and the continuous metal fill portion, and a second high-k dielectric layer, where the second work function metal layer is disposed between the second high-k dielectric layer and the continuous metal fill portion.

In embodiments, the semiconductor device may further include a first set of inner spacers disposed between at least two consecutive channel layers of the at least one n-type transistor device, where the first high-k dielectric layer contacts at least a portion of the first set of inner spacers and the at least two consecutive channel layers of the at least one n-type transistor device.

In embodiments, the semiconductor device may further include a second set of inner spacers disposed between at least two consecutive channel layers of the at least one p-type transistor device, where the second high-k dielectric layer contacts at least a portion of the second set of inner spacers and the at least two consecutive channel layers of the at least one p-type transistor device.

In embodiments, the semiconductor device may further include a first source/drain region that contacts one or more channel layers of the least one n-type transistor device, and a second source/drain region that contacts one or more channel layers of the least one p-type transistor device.

In embodiments, the semiconductor device may further include an interconnect layer disposed beneath the first one of the at least two high-k free dielectric layers, one or more frontside contacts connected to the first source/drain region and the interconnect layer, and one or more backside contacts connected to the second source/drain region and the interconnect layer.

In another exemplary embodiment, a method includes removing first portions of a sacrificial gate layer surrounding one or more upper channel layers of an upper transistor device of semiconductor structure, where the semiconductor structure includes a lower transistor device comprising one or more lower channel layers, and forming a first high-K metal gate structure that covers at least exposed surfaces of the one or more upper channel layers. The method includes filling the removed first portions of the sacrificial gate layer with a metal gate material, removing second portions of the sacrificial gate layer that surround the one or more lower channel layers, and forming a second high-K metal gate structure that covers at least exposed surfaces of the one or more lower channel layers. The method also includes filling the removed second portions of the sacrificial gate layer with the metal gate material to form a common gate structure, where the metal gate material is continuous between the upper transistor device and the lower transistor device, and where a bottom surface of the metal gate material directly contacts a first high-k free dielectric layer, and a top surface of the metal gate material directly contacts a second high-k free dielectric layer.

In embodiments, the upper transistor device and the lower transistor device may have opposing polarities.

In embodiments, the first high-K metal gate structure may include a first work metal function material that is matched to the upper transistor device, and the second high-K metal gate structure may include a second work metal function material that is matched to the lower transistor device, where the first work metal function material is different than the second work metal function material.

In embodiments, the upper transistor device may include one of an n-type transistor device and a p-type transistor device, and the lower transistor device may include the other one of the n-type transistor device and the p-type transistor device.

Semiconductor devices and methods for forming the same in accordance with the above-described techniques can be employed in various applications, hardware, and/or electronic systems. Suitable hardware and systems for implementing embodiments of the present disclosure may include, but are not limited to, personal computers, communication networks, electronic commerce systems, portable communications devices (for example, cell and smart phones), solid-state media storage devices, functional circuitry, etc. Systems and hardware incorporating the semiconductor devices are contemplated embodiments of the present disclosure. Given the teachings provided herein, one of ordinary skill in the art will be able to contemplate other implementations and applications of embodiments of the present disclosure.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard; or (b) an end product. The end product can be any product that includes integrated circuit chips, ranging from toys and other low-end applications to advanced computer products having a display, a keyboard or other input device, and a central processor.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments described herein have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
at least one stacked device structure comprising at least one upper transistor device comprising one or more upper channel layers, and at least one lower transistor device comprising one or more lower channel layers;
at least two high-k free dielectric layers; and
a common gate structure comprising a metal fill portion, wherein a first side of the metal fill portion contacts a first one of the at least two high-k free dielectric layers, and a second side of the metal fill portion contacts a second one of the at least two high-k free dielectric layers.

2. The semiconductor device of claim 1, wherein the at least one upper transistor device and the at least one lower transistor device have opposing polarities.

3. The semiconductor device of claim 1, wherein the common gate structure further comprises a first work function metal layer associated with the at least one upper transistor device and a second work function metal layer associated with the at least one lower transistor device, wherein the first work function metal layer comprises a different material than the second work function metal layer.

4. The semiconductor device of claim 1, further comprising:
a first source/drain region that contacts the one or more upper channel layers; and
a second source/drain region that contacts the one or more lower channel layers.

5. The semiconductor device of claim 4, further comprising:
a dielectric barrier disposed between the first source/drain region and the second source/drain region.

6. The semiconductor device of claim 4, further comprising:
a backside interconnect layer;
one or more frontside contacts connected to the first source/drain region and the backside interconnect layer; and
one or more backside contacts connected to the second source/drain region and the backside interconnect layer.

7. The semiconductor device of claim 1, wherein the at least one upper transistor device comprises one of an n-type transistor device and a p-type transistor device, and the at least one lower transistor device comprises the other one of the n-type transistor device and the p-type transistor device.

8. The semiconductor device of claim 1, wherein the metal fill portion of the common gate structure is continuous between the at least one upper transistor device and the at one least lower transistor device.

9. A semiconductor device comprising:
at least one stacked transistor structure comprising at least one n-type transistor device and at least one p-type transistor device adjacent to the least one n-type transistor device;
at least two high-k free dielectric layers; and
a common gate structure comprising a continuous metal fill portion, wherein a bottom surface of the continuous metal fill portion directly contacts a first one of the at least two high-k free dielectric layers, and a top surface of the continuous metal fill portion directly contacts a second one of the at least two high-k free dielectric layers.

10. The semiconductor device of claim 9, wherein the at least one n-type transistor device and the at least one p-type transistor device have opposing polarities.

11. The semiconductor device of claim 9, wherein the common gate structure further comprises a first work function metal layer associated with the n-type transistor device and a second work function metal layer associated with the p-type transistor device, wherein the first work function metal layer comprises a different material than the second work function metal layer.

12. The semiconductor device of claim 11, wherein the common gate structure further comprises:
a first high-k dielectric layer, wherein the first work function metal layer is disposed between the first high-k dielectric layer and the continuous metal fill portion; and
a second high-k dielectric layer, wherein the second work function metal layer is disposed between the second high-k dielectric layer and the continuous metal fill portion.

13. The semiconductor device of claim 12, further comprising:
a first set of inner spacers disposed between at least two consecutive channel layers of the at least one n-type transistor device, wherein the first high-k dielectric layer contacts at least a portion of the first set of inner spacers and the at least two consecutive channel layers of the at least one n-type transistor device.

14. The semiconductor device of claim 13, further comprising:
a second set of inner spacers disposed between at least two consecutive channel layers of the at least one p-type transistor device, wherein the second high-k dielectric layer contacts at least a portion of the second set of inner spacers and the at least two consecutive channel layers of the at least one p-type transistor device.

15. The semiconductor device of claim 9, further comprising:
a first source/drain region that contacts one or more channel layers of the least one n-type transistor device; and
a second source/drain region that contacts one or more channel layers of the least one p-type transistor device.

16. The semiconductor device of claim 15, further comprising:
an interconnect layer disposed beneath the first one of the at least two high-k free dielectric layers;
one or more frontside contacts connected to the first source/drain region and the interconnect layer; and
one or more backside contacts connected to the second source/drain region and the interconnect layer.

17. A method comprising:
removing first portions of a sacrificial gate layer surrounding one or more upper channel layers of an upper transistor device of semiconductor structure, wherein the semiconductor structure comprises a lower transistor device comprising one or more lower channel layers;
forming a first high-K metal gate structure that covers at least exposed surfaces of the one or more upper channel layers;
filling the removed first portions of the sacrificial gate layer with a metal gate material;
removing second portions of the sacrificial gate layer that surround the one or more lower channel layers;
forming a second high-K metal gate structure that covers at least exposed surfaces of the one or more lower channel layers; and
filling the removed second portions of the sacrificial gate layer with the metal gate material to form a common gate structure, wherein the metal gate material is continuous between the upper transistor device and the lower transistor device, and wherein a bottom surface of the metal gate material directly contacts a first high-k free dielectric layer and a top surface of the metal gate material directly contacts a second high-k free dielectric layer.

18. The method of claim 17, wherein the upper transistor device and the lower transistor device have opposing polarities.

19. The method of claim 17, wherein the first high-K metal gate structure comprises a first work metal function material that is matched to the upper transistor device and the second high-K metal gate structure comprises a second work metal function material that is matched to the lower transistor device, wherein the first work metal function material is different than the second work metal function material.

20. The method of claim 17, wherein the upper transistor device comprises one of an n-type transistor device and a p-type transistor device, and the lower transistor device comprises the other one of the n-type transistor device and the p-type transistor device.
